(19) United States
(12) Patent Application Publication
(10) Pub. No.: US 2016/0043136 A1
(43) Pub. Date: Feb. 11, 2016

(54) MAGNETIC MEMORY DEVICES

(71) Applicant: SAMSUNG ELECTRONICS CO., LTD., Suwon-si (KR)

(72) Inventors: Sung-in KIM, Hwaseong-si (KR); Jae-kyu LEE, Yongin-si (KR)

(21) Appl. No.: 14/677,101

(22) Filed: Apr. 2, 2015

(30) Foreign Application Priority Data
Aug. 8, 2014 (KR) 10 2014 0102624

(51) Int. Cl. H01L 27/22; H01L 23/535

(52) U.S. Cl. CPC H01L 27/228; H01L 23/535

(57) ABSTRACT

A magnetic memory device is provided. The magnetic memory device includes a substrate including a first source/drain region and a second source/drain region; a word line structure between the first and source/drain regions and extending in a first direction; a buried contact electrically connected to the first source/drain region and on the first source/drain region; a contact pad electrically connected to the buried contact and on the buried contact; and a memory portion electrically connected to the contact pad and on the contact pad, the contact pad including a metal silicide layer.

### CROSS-REFERENCE TO RELATED APPLICATION

This application claims priority under 35 USC §119 to Korean Patent Application No. 10-2014-0102624, filed on Aug. 8, 2014, in the Korean Intellectual Property Office, and entitled: “Magnetic Memory Devices,” which is incorporated by reference herein in its entirety.

### BACKGROUND

1. Field

Provided are memory devices, for example, magnetic memory devices.

2. Description of the Related Art

In the electronics industry, semiconductor devices may be attractive, for example, because of compact size, multi-functionality, and/or low fabrication costs thereof. Next-generation semiconductor memory devices may have or require high operation speed, nonvolatile characteristics, and low operation voltages. Magnetic memory devices may be a next-generation semiconductor memory device, and may have improved integration density, operation speed, and reliability.

### SUMMARY

Embodiments may be realized by providing a magnetic memory device, including a substrate including a first source/drain region and a second source/drain region; a word line structure disposed between the first and second source/drain regions and extending in a first direction; a buried contact electrically connected to the first source/drain region and disposed on the first source/drain region; a contact pad electrically connected to the buried contact and disposed on the buried contact, the contact pad including a metal silicide layer; and a memory portion electrically connected to the contact pad and on the contact pad. the

The metal silicide layer may include one or more of a cobalt silicide layer, a titanium silicide layer, a tantalum silicide layer, a tungsten silicide layer, a nickel silicide layer, or a platinum silicide layer.

A width of the metal silicide layer in a second direction perpendicular to the first direction may be greater than a width of the buried contact in the second direction.

The memory portion may include a bottom electrode, a magnetic tunnel junction element, and a top electrode, which are sequentially stacked; and the magnetic tunnel junction element may include a pinned layer, a tunnel barrier layer, and a free layer.

The buried contact may include a polysilicon material.

The contact pad may further include a polysilicon pad.

The polysilicon pad may contact the buried contact, and the metal silicide layer may contact the memory portion.

A width of the polysilicon pad in a second direction perpendicular to the first direction may be substantially equal to a width of the metal silicide layer in the second direction.

The contact pad may further include a metal pad.

The metal silicide layer may contact the buried contact, and the metal pad may contact the memory portion.

The magnetic memory device may further include a source line structure electrically connected to the second source/drain region and extending in the first direction. The source line structure may include a source line contact contacting the second source/drain region, a source metal silicide layer on the source line contact, and a source line on the source metal silicide layer.

Embodiments may be realized by providing a magnetic memory device, including a substrate including an active region defined by an isolation layer; a first source/drain region and a second source/drain region in the active region; a word line structure disposed between the first and source/drain regions and extending in a first direction; a buried contact disposed on the first source/drain region and electrically connected to the first source/drain region, the buried contact including a polysilicon material; a contact pad disposed on the buried contact and electrically connected to the buried contact, the contact pad including a polysilicon pad and a first metal silicide layer, which are sequentially stacked; a memory portion disposed on the first metal silicide layer and electrically connected to the contact pad; a source line structure disposed on the second source/drain region and electrically connected to the second source/drain region; and a bit line extending in a second direction perpendicular to the first direction and electrically connected to the memory portion.

A width of the polysilicon pad in the second direction may be substantially equal to a width of the first metal silicide layer in the second direction.

The source line structure may include a source line contact contacting the second source/drain region, a second metal silicide layer on the source line contact, and a source line on the second metal silicide layer; and a width of the first metal silicide layer in the second direction may be greater than a width of the second metal silicide layer in the second direction.

The memory portion may include a bottom electrode, a magnetic tunnel junction element, and a top electrode, which are sequentially stacked; and the magnetic tunnel junction element may include a pinned layer, a tunnel barrier layer, and a free layer.

The magnetic memory device may further include an insulation layer being at a lower level than the memory portion and covering a sidewall of the contact pad. The insulation layer may include an overlap region that vertically overlaps an edge of the memory portion and a non-overlap region that does not vertically overlap the memory portion, and the non-overlap region of the insulation layer may have a top surface at lower level than a top surface of the overlap region.

Embodiments may be realized by providing a magnetic memory device, including a substrate including a first source/drain region and a second source/drain region; a word line structure disposed between the first and source/drain regions and extending in a first direction; a buried contact electrically connected to the first source/drain region and disposed on the first source/drain region, an upper width of the buried contact in a second direction perpendicular to the first direction being greater than a lower width of the buried contact in the second direction; a contact pad electrically connected to the buried contact and disposed on the buried contact, the contact pad including the metal silicide layer; and a memory portion electrically connected to the contact pad and disposed on the contact pad.

The buried contact may have a sloped sidewall.

The contacts pad may further include a polysilicon pad contacting the metal silicide layer and the metal silicide layer contacts the memory portion.

The contact pad may further include a metal pad on the metal silicide layer; the metal silicide layer may be between the metal pad and the contact; and a width of the metal silicide layer in the second direction may be substantially equal to the upper width of the buried contact in the second direction.

### BRIEF DESCRIPTION OF THE DRAWINGS

Features will become apparent to those of skill in the art by describing in detail exemplary embodiments with reference to the attached drawings in which:

FIG. 1 illustrates circuit diagram of a cell array of a magnetic memory device according to an embodiment;

FIG. 2A illustrates a plan view of a cell array of a magnetic memory device according to an embodiment;

FIG. 2B illustrates a cross-sectional view taken along a line B1-B1′ of FIG. 2A;

FIGS. 3, 4 and 5 illustrate cross-sectional views taken along line B1-B1′ of FIG. 2A to illustrate magnetic memory devices according to other embodiments;

FIGS. 6A and 6B illustrate plan views of cell arrays of magnetic memory devices according to other embodiments;

FIGS. 7A to 7S illustrate cross-sectional views of a method of fabricating a magnetic memory device, according to an embodiment;

FIGS. 8A, 8B, and 8C illustrate cross-sectional views of a method of fabricating the magnetic memory device shown in FIG. 3;

FIGS. 9A to 9H illustrate cross-sectional views of a method of fabricating the magnetic memory device shown in FIG. 5; and

FIG. 10 illustrates a block diagram of an electronic system including at least one magnetic memory device according to some embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals in the drawings denote like elements, and their description may be omitted to avoid duplicate explanation.

The following embodiments may be embodied in many different forms and should not be construed as being limited to the embodiments set forth herein. Rather, these embodiments are provided so that this disclosure will be thorough and complete, and will fully convey the concept of example embodiments to those of skill in the art.

It will be understood that, although the terms “first”, “second”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Unless otherwise defined, all terms (including technical and scientific terms) used herein have the same meaning as commonly understood by one of skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Moreover, in method embodiments such as fabrication method embodiments, process steps of the methods may be performed in different sequences from the order which is described in the specification unless the context clearly indicates otherwise. That is, the process steps of the methods may be performed in the same sequence as described in the specification or in an opposite sequence thereto.

Additionally, in the accompanying drawings, shapes of the exemplary views may be modified according to manufacturing techniques and/or allowable errors. Therefore, the embodiments are not limited to the specific shape illustrated in the exemplary views, but may include other shapes that may be created according to manufacturing processes.

As used herein, the term “and/or” includes any and all combinations of one or more of the associated listed items. Expressions such as “at least one of,” when preceding a list of elements, modify the entire list of elements and do not modify the individual elements of the list.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

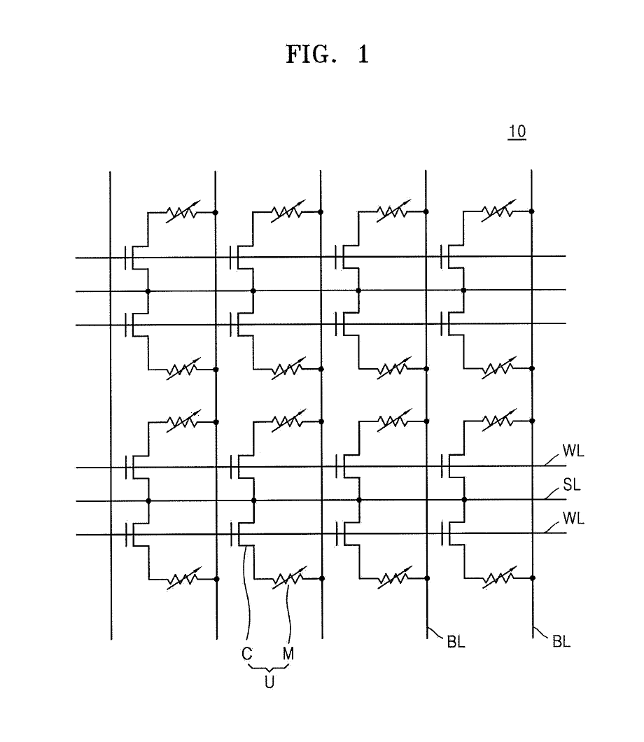

FIG. 1 illustrates circuit diagram of a portion of a cell array 10 of a magnetic memory device according to an embodiment. Referring to FIG. 1, the cell array 10 may include a plurality of unit cells U that are arrayed in a matrix form. Each unit cell U may include an access portion C and a memory portion M. Each unit cell U may be electrically connected to one of a plurality of parallel word lines WL and one of a plurality of parallel bit lines BL. The plurality of parallel word lines WL may intersect the plurality of parallel bit lines BL. For example, the plurality of parallel word lines WL and the plurality of parallel bit lines BL may be two-dimensionally arrayed. The access portion C may be realized using a transistor, and a source of the access portion C may be electrically connected to one of a plurality of source lines SL.

The access portion C may control the current supply to the memory portion M in response to a voltage of the word line WL connected to the access portion C. In some embodiments, the access portion C may be a MOS transistor, a bipolar transistor or a diode.

The memory portion M may include a magnetic material. For example, the memory portion M may include a magnetic tunnel junction (MTJ) element. In some embodiments, data may be stored in the memory portion M by using a spin transfer torque (STT) phenomenon that a magnetization direction of a magnetic material is changed by a current flowing through the memory portion M.

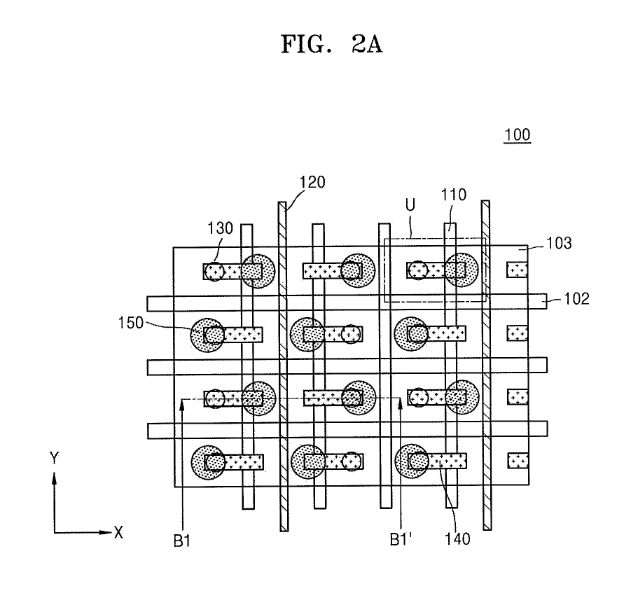

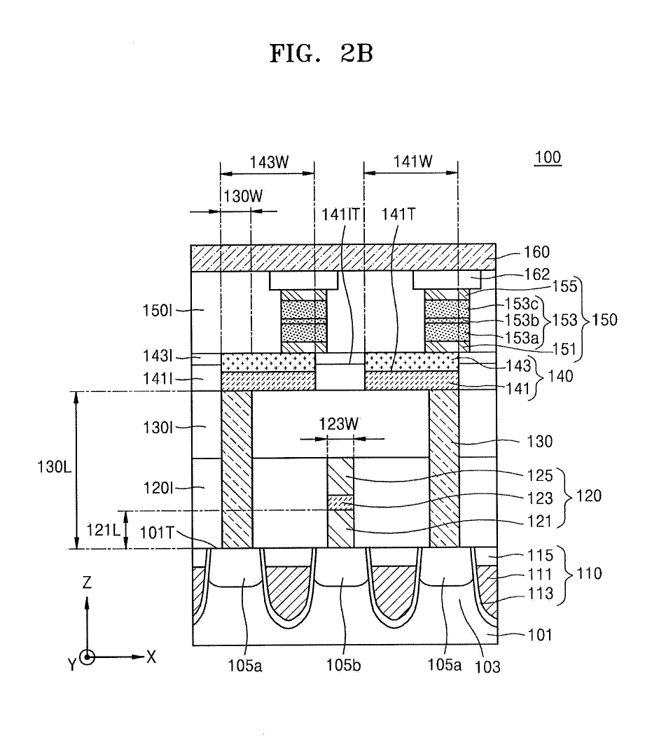

FIG. 2A illustrates a plan view of a cell array of a magnetic memory device 100 according to an embodiment, and FIG. 2B illustrates a cross-sectional view taken along a line B1-B1′ of FIG. 2A. FIG. 2A may be a layout diagram corresponding to the circuit diagram of FIG. 1. The magnetic memory device 100 may be applied to a magnetic memory device including a memory cell having a cell size of 6F2 or 7F2 (wherein, ‘F’ denotes a minimum lithography feature size).

Referring to FIGS. 2A and 2B, the magnetic memory device 100 may include a plurality of unit cells U that are two-dimensionally arrayed along rows and columns. The rows may be parallel with a first direction (i.e., an X-axis direction), and the columns may be parallel with a second direction (i.e., a Y-axis direction) which is perpendicular to the first direction. For example, isolation layers 102 may be formed in a substrate 101 to define active regions 103 having linear shapes. The active regions 103 may be arrayed in the second direction and may be parallel with the first direction. The active regions 103 may be arrayed such that distances between the active regions 103 are equal to each other. The isolation layers 102 may also be arrayed in the second direction and may be parallel with the first direction.

The substrate 101 may be a semiconductor substrate. For example, the substrate 101 may include a simple semiconductor material or a compound semiconductor material. The simple semiconductor material may be a silicon (Si) material or a germanium (Ge) material, and the compound semiconductor material may be a silicon germanium (SiGe) material, a silicon carbide (SiC) material, a gallium arsenide (GaAs) material, an indium arsenide (InAs) material, or an indium phosphide (InP) material. In an embodiment, the substrate 101 may be a silicon-on-insulator (SOI) substrate. The substrate 101 may include a conductive region doped with impurities. For example, the substrate 101 may include a well region.

Word line structures 110 may be arrayed in the first direction, and each of the word line structures 110 may extend in the second direction. Each of the word line structures 110 may include a word line 111, a gate dielectric layer 113 disposed between the substrate 101 and the word line 111, and a mask insulation layer 115 disposed on a top surface of the word line 111.

In some embodiments, the word line 111 may be buried in the substrate 101 such that a top surface of the word line 111 is at a lower level than a top surface 101T of the substrate 101. In other embodiments, only a portion of the word line 111 may be buried in the substrate 101. In other embodiments, although not shown in the drawings, the word line 111 may be disposed on the top surface 101T of the substrate 101.

The word line 111 may include one or more of a silicon material, a metal material, a conductive metal nitride material, or a metal silicide material.

The gate dielectric layer 113 may include one or more of a silicon oxide layer, a silicon nitride layer, a silicon oxynitride layer, an oxide/nitride/oxide (0/N/0) layer, or a high-k dielectric layer.

The mask insulation layer 115 may include one or more of a silicon oxide layer, a silicon nitride layer, or a silicon oxynitride layer.

Each of the active regions 103 may include a plurality of first source/drain regions 105a and a plurality of second source/drain regions 105b. The first source/drain regions 105a and the second source/drain regions 105b may be alternately arrayed along the first direction (i.e., the X-axis direction) in each active region 103. In each active region 103, the first and second source/drain regions 105a and 105b may be separated from each other by the word line structures 110. The first and second source/drain regions 105a and 105b may be formed using, for example, an ion implantation process. In each active region 103, the first source/drain region 105a, the second source/drain region 105b adjacent to first source/drain region 105a, and the word line 110 between the adjacent first and second source/drain regions 105a and 105b may constitute an access transistor corresponding to an access portion (‘C’ of FIG. 1) of the unit cell U.

A first interlayer insulation layer 120I may be disposed on the substrate 101. The first interlayer insulation layer 120I may include a silicon oxide layer, a silicon nitride layer, or a combination thereof. For example, the first interlayer insulation layer 120I may be a tetraethyl orthosilicate (TEOS) layer or a high density plasma (HDP) oxide layer. FIG. 2B illustrates an example in which the first interlayer insulation layer 120I consists of a single material layer. In some embodiments, the first interlayer insulation layer 120I may include a plurality of insulation layers.

Source line structures 120 may be disposed on the substrate 101. The source line structures 120 may extend in the second direction to overlap with the second source/drain regions 105b. The source line structures 120 may be disposed in the first interlayer insulation layer 120I and may be electrically connected to the second source/drain regions 105b. In a plan view, the source line structures 120 may be disposed between the word line structures 110. Each of the source line structures 120 may include a source line contact 121, a source metal silicide layer 123, and a source line 125.

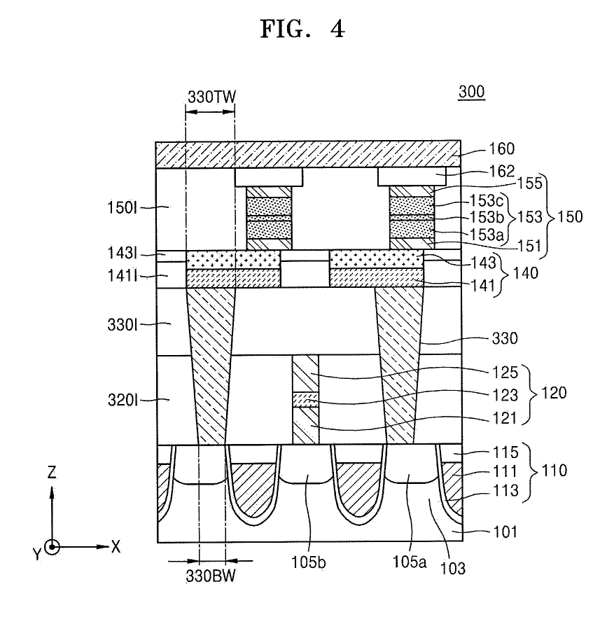

In some embodiments, as illustrated in FIG. 2B, the source line contact 121, the source metal silicide layer 123, and the source line 125 may have substantially the same width in the first direction. In other embodiments, the source line contact 121, the source metal silicide layer 123, and the source line 125 may have different widths in the first direction. In still other embodiments, each of the source line structures 120 may have a reverse trapezoid form in a cross-sectional view, like buried contacts 330 illustrated in FIG. 4.

The source line contact 121 may be disposed on the second source/drain region 105b to electrically connect the source line 125 to the second source/drain region 105b. In some embodiments, the source line contact 121 may include one or more of a doped silicon layer, a metal layer, a conductive metal nitride layer, or a metal silicide layer.

The source line 125 may extend in the second direction and be parallel with the word line structures 110. The source line 125 may be electrically connected to the second source/drain regions 105b through the source line contact 121 thereunder.

The source line 125 may include a metal layer or a conductive metal nitride layer. The source line 125 may have a single-layered structure or a multi-layered structure. For example, the source line 125 may have a multi-layered structure that includes a titanium layer, a titanium nitride layer, and a tungsten layer which are stacked.

The source metal silicide layer 123 may be disposed between the source line contact 121 and the source line 125. The source metal silicide layer 123 may reduce a contact resistance between the source line contact 121 and the source line 125.

The source metal silicide layer 123 may include one or more of a cobalt silicide layer, a titanium silicide layer, a tantalum silicide layer, a tungsten silicide layer, a nickel silicide layer, or a platinum silicide layer.

In some embodiments, the source line 125 may directly contact the source line contact 121 without the source metal silicide layer 123 therebetween.

A second interlayer insulation layer 130I may be disposed on the first interlayer insulation layer 120I and the source line structures 120. The second interlayer insulation layer 130I may be a silicon oxide layer, a silicon nitride layer, or a combination thereof.

Buried contacts 130 may be disposed on the first source/drain regions 105a, respectively. Each of the buried contacts 130 may penetrate the first and second interlayer insulation layers 120I and 130I and be electrically connected to any one of the first source/drain regions 105a.

In some embodiments, the buried contacts 130 may be arrayed along the first and second directions to have a matrix form, as illustrated in FIG. 2A. On each active region 103, two adjacent buried contacts 130 located at both sides of each source line structure 120 may be disposed to be symmetric with respect to the source line structure 120 therebetween. Each of the buried contacts 130 may include, for example, a doped polysilicon layer.

Each of the buried contacts 130 may have an upper width in the first direction (i.e., the X-axis direction) that is substantially equal to a lower width in the first direction (i.e., the X-axis direction).

In some embodiments, the buried contacts 130 may have a height 130L in a third direction (i.e., a Z-axis direction) that is perpendicular to both the first and second directions, and the height 130L of the buried contacts 130 may be greater than a height 121L of the source line contacts 121 in the third direction.

In some embodiments, the height 121L of the source line contacts 121 may be within the range of about 300 angstroms to about 1000 angstroms, and the height 130L of the buried contacts 130 may be within the range of about 1500 angstroms to about 2500 angstroms.

Contact pads 140 may be disposed on the buried contacts 130, respectively. Each of the contact pads 140 may extend on the second interlayer insulation layer 130I. The contact pads 140 may be electrically connected to the first source/drain regions 105a through the buried contacts 130.

The contact pads 140 may be arrayed in a matrix form such that central points of the contact pads 140 are located on horizontal straight lines extending in the first direction (i.e., the X-axis direction) and vertical straight lines extending in the second direction (i.e., the Y-axis direction), as illustrated in FIG. 2A. On each active region 103, in a plan view, two adjacent contact pads 140 located at both sides of each source line structure 120 may be disposed to be symmetric with respect to the source line structure 120 therebetween.

A width of each contact pad 140 in the first direction (i.e., the X-axis direction) may be greater than a width of each contact pad 140 in the second direction (i.e., the Y-axis direction), as illustrated in FIG. 2A. A layout margin of memory portions 150, which may be respectively disposed on the contact pads 140, may be improved. For example, distances between the memory portions 150 may be maximized.

Each of the contact pads 140 may include a polysilicon pad 141 and a pad metal silicide layer 143 which are sequentially stacked.

The polysilicon pad 141 may include a doped polysilicon layer, and the pad metal silicide layer 143 may be self-aligned with the polysilicon pad 141. In some embodiments, the pad metal silicide layer 143 may correspond to a silicide material which is formed by performing a silicidation process on the polysilicon pad 141. The pad metal silicide layer 143 may be disposed between the polysilicon pad 141 and the memory portion 150 to reduce a contact resistance between the polysilicon pad 141 and the memory portion 150.

A width 143W of each pad metal silicide layer 143 in the first direction (i.e., the X-axis direction) may be greater than a width 130W of each buried contact 130 in the first direction (i.e., the X-axis direction). In some embodiments, a width 143W of each pad metal silicide layer 143 in the first direction (i.e., the X-axis direction) may be substantially equal to a width 141W of each polysilicon pad 141 in the first direction (i.e., the X-axis direction). In some embodiments, the width 143W of each pad metal silicide layer 143 in the first direction (i.e., the X-axis direction) may be greater than a width 123W of each source metal silicide layer 123 in the first direction (i.e., the X-axis direction).

In some embodiments, the pad metal silicide layers 143 may be located at a higher level than the source lines 125.

A third interlayer insulation layer 141I and a fourth interlayer insulation layer 143I may be disposed to cover sidewalls of the contact pads 140. The third interlayer insulation layer 141I may include a silicon oxide layer, a silicon nitride layer, or a combination thereof. The fourth interlayer insulation layer 143I may also include a silicon oxide layer, a silicon nitride layer, or a combination thereof. A top surface of the fourth interlayer insulation layer 143I may be substantially coplanar with top surfaces of the pad metal silicide layers 143.

In some embodiments, a top surface 141IT of the third interlayer insulation layer 141I may be located at a higher level than top surfaces 141T of the polysilicon pads 141. In some embodiments, the third interlayer insulation layer 141I may be disposed to fully cover the sidewalls of the contact pads 140 without the fourth interlayer insulation layer 143I thereon. Thus, the top surface 141IT of the third interlayer insulation layer 141I may be substantially coplanar with the top surfaces of the pad metal silicide layers 143.

The memory portions 150 may be disposed on the contact pads 140, respectively. Each of the memory portions 150 may laterally extend to cover a portion of the fourth interlayer insulation layer 143I. The memory portions 150 may be electrically connected to the contact pads 140, respectively. The memory portions 150 may be separated from each other by a fifth interlayer insulation layer 150I.

The memory portions 150 may be arrayed such that central points of the memory portions 150 are located on a straight line extending in the first direction (i.e., the X-axis direction). In each column, the memory portions 150 may be arrayed in a zigzag fashion along the second direction (i.e., the Y-axis direction). Each of the memory portions 150 may include a bottom electrode 151, a magnetic tunnel junction (MTJ) element 153, and a top electrode 155.

The bottom electrode 151 may electrically connect the MTJ element 153 to the contact pad 140, and the top electrode 155 may electrically connect the MTJ element 153 to one of a plurality of bit lines 160.

In some embodiments, each of the bottom electrodes 151 may include a metal layer or a metal nitride layer, and each of the top electrodes 155 may also include a metal layer or a metal nitride layer. For example, each of the bottom electrodes 151 may include a titanium nitride layer.

The MTJ element 153 may be disposed between the bit line 160 and the contact pad 140 to store a datum therein. The MTJ element 153 may include a pinned layer 153a connected to the bottom electrode 151, a free layer 153c connected to the top electrode 155, and a tunnel barrier layer 153b disposed between the pinned layer 153a and the free layer 153c.

The pinned layer 153a of the MTJ element 153 may be configured to have fixed magnetic polarization, which is parallel with one direction. Magnetic polarization of the free layer 153c may be changeable to be parallel or anti-parallel with the fixed magnetic polarization of the pinned layer 153a, and the datum “0” or “1” may be stored in the MTJ element 153 based on the magnetic polarization of the free layer 153c. For example, when the magnetic polarization of the free layer 153c is parallel with the fixed magnetic polarization of the pinned layer 153a, the MTJ element 153 may have a relatively low resistance value to have a datum “0”. In contrast, when the magnetic polarization of the free layer 153c is anti-parallel with the fixed magnetic polarization of the pinned layer 153a, the MTJ element 153 may have a relatively high resistance value to have a datum “1”.

The pinned layer 153a may include a ferromagnetic material such as a cobalt-iron (CoFe) material, a nickel-iron (NiFe) material, or an iron-manganese (FeMn) material. The free layer 153c may also include a ferromagnetic material such as a cobalt-iron (CoFe) material, a nickel-iron (NiFe) material, or an iron-manganese (FeMn) material. The pinned layer 153a may further include an anti-ferromagnetic material for pinning the magnetic polarization thereof. The tunnel barrier layer 153b may include one or more of a magnesium oxide material, a titanium oxide material, an aluminum oxide material, a zinc magnesium oxide material, or a boron magnesium oxide material. The bottom electrode 151 may include a conductive metal nitride material, for example, a titanium nitride material, a tantalum nitride material, and/or a tungsten nitride material. The top electrode 155 may also include a conductive metal nitride material, for example, a titanium nitride material, a tantalum nitride material, and/or a tungsten nitride material.

In the present embodiment, the pad metal silicide layer 143 may be self-aligned with the polysilicon pad 141, a planar area of the pad metal silicide layer 143 in an X-Y plane may increase to reduce an interfacial resistance of the pad metal silicide layer 143, and sufficient current may be supplied to the MTJ element 153 through the pad metal silicide layer 143.

The bit lines 160 may be disposed on the fifth interlayer insulation layer 150I and the memory portions 150. The bit lines 160 are not illustrated in FIG. 2A so as to clearly view the buried contacts 130, the contact pads 140, and the memory portions 150.

The bit lines 160 may extend in the first direction (i.e., the X-axis direction). Although not shown in FIG. 2A, the bit lines 160 may be arrayed in the second direction (i.e., the Y-axis). The bit lines 160 may be electrically connected to the memory portions 150 through bit line contacts 162.

Each of the bit lines 160 may include a metal material and/or a conductive metal nitride material. For example, each of the bit lines 160 may include an aluminum material, a copper material, a tantalum nitride material, and/or a titanium nitride material.

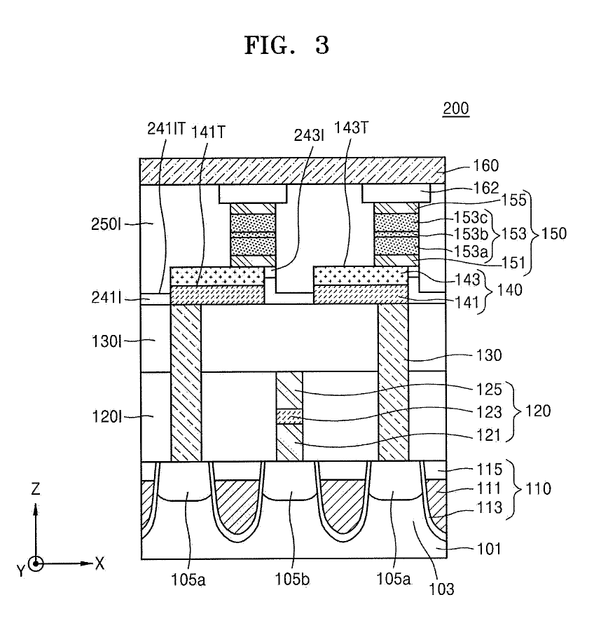

FIGS. 3, 4 and 5 illustrate cross-sectional views taken along a line B1-B1′ of FIG. 2A to illustrate magnetic memory devices 200, 300, and 400 according to other embodiments. In FIGS. 3, 4 and 5, the same reference numerals or the same reference designators as used in FIGS. 1, 2A and 2B denote the same elements, and descriptions of the same components as set forth in the previous embodiments will be omitted or briefly mentioned in this embodiment to avoid duplicate explanation.

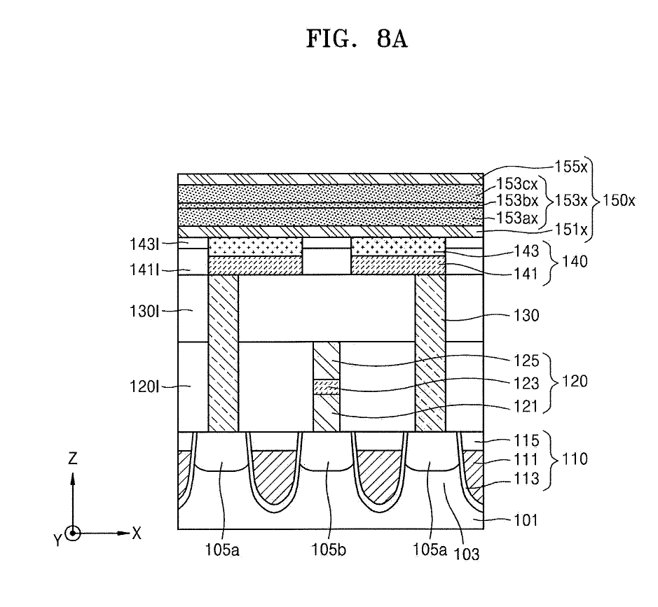

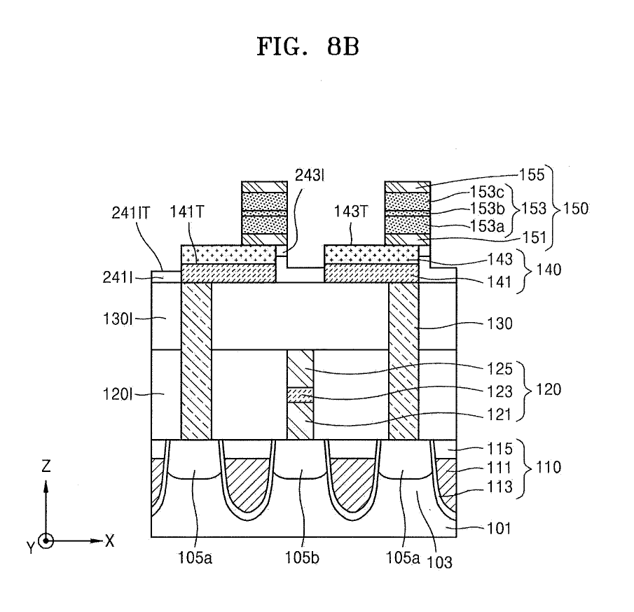

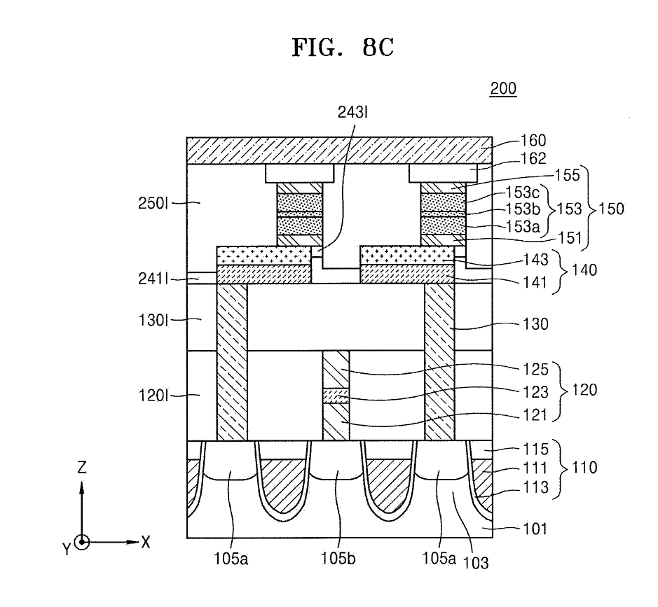

Referring to FIG. 3, the magnetic memory device 200 may include the word line structures 110, the source line structures 120, the first and second source/drain regions 105a and 105b, the buried contacts 130, the contact pads 140, the memory portions 150, the bit lines 160, the first and second interlayer insulation layers 120I and 130I, a third interlayer insulation layer 241I, a fourth interlayer insulation layer 243I, and a fifth interlayer insulation layer 250I. A method of fabricating the magnetic memory device 200 will be described with reference to FIGS. 8A, 8B, and 8C.

The magnetic memory device 200 may have a similar structure to the magnetic memory device 100. The magnetic memory device 200 may differ from the magnetic memory device 100 in terms of configurations of the third, fourth, and fifth interlayer insulation layers 241I, 243I and 250I.

The third interlayer insulation layer 241I may be disposed on the second interlayer insulation layer 130I to cover a portion of a sidewall of each of the contact pads 140. The fourth interlayer insulation layer 243I may be disposed on the third interlayer insulation layer 241I to cover the other portion of the sidewall of each of the contact pads 140. The third interlayer insulation layer 241I may include a silicon oxide layer, a silicon nitride layer, or a combination thereof. The fourth interlayer insulation layer 243I may also include a silicon oxide layer, a silicon nitride layer, or a combination thereof.

The memory portions 150 may be formed by over-etching the fourth and third interlayer insulation layers 243I and 241I (see FIG. 8B), and an end point of the over-etching process for forming the memory portions 150 may be lower than top surfaces 143T of the pad metal silicide layers 143.

As a result of the over-etching process for forming the memory portions 150, the fourth interlayer insulation layer 243I may vertically overlap with a portion of each of the memory portions 150. A top surface 241IT of the third interlayer insulation layer 241I may have stepped profiles. For example, the third interlayer insulation layer 241I may include overlap regions vertically overlapping with the memory portions 150 and a non-overlap region having a top surface which is at a lower level than top surfaces of the overlap regions thereof.

The pad metal silicide layers 143 may function as etch stop layers while the over-etching process for forming the memory portions 150 is performed, and during the over-etching process for forming the memory portions 150, the pad metal silicide layers 143 may prevent the contact pads 140 from being deformed and may prevent the memory portions 150 from being abnormally patterned.

Referring to FIG. 4, the magnetic memory device 300 may include the word line structures 110, the source line structures 120, buried contacts 330, the contact pads 140, the memory portions 150, the bit lines 160, the third, fourth, and fifth interlayer insulation layers 141I, 143I and 150I, a first interlayer insulation layer 320I, and a second interlayer insulation layer 330I.

The magnetic memory device 300 may have a similar structure to the magnetic memory device 100. The magnetic memory device 300 may differ from the magnetic memory device 100 in terms of configurations of the buried contacts 330. The first and second interlayer insulation layers 320I and 330I may correspond to the first and second interlayer insulation layers 120I and 130I illustrated in FIG. 3, respectively.

For example, an upper width 330TW of each buried contact 330 in the first direction (i.e., the X-axis direction) may be greater than a lower width 330BW of each buried contact 330 in the first direction (i.e., the X-axis direction). In some embodiments, a width of each buried contact 330 in the first direction (i.e., the X-axis direction) may gradually increase away from the substrate 101 in the third direction (i.e., the Z-axis direction). For example, each of the buried contacts 330 may have a sloped sidewall.

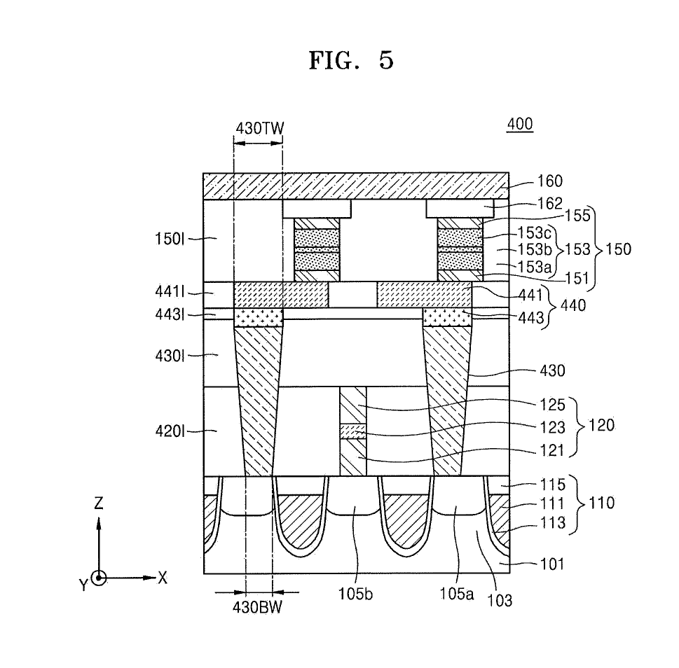

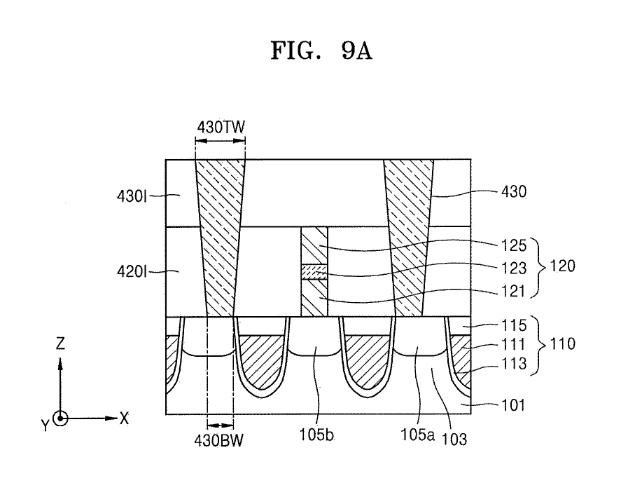

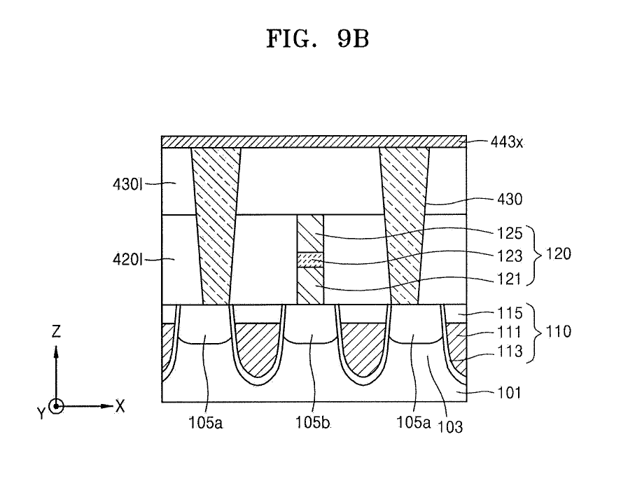

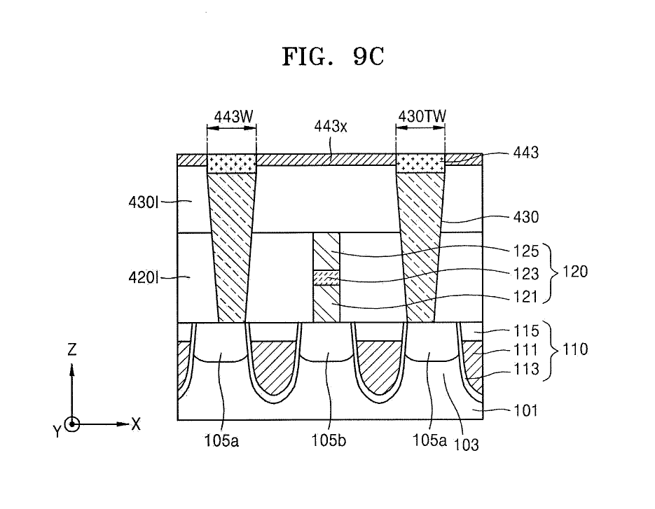

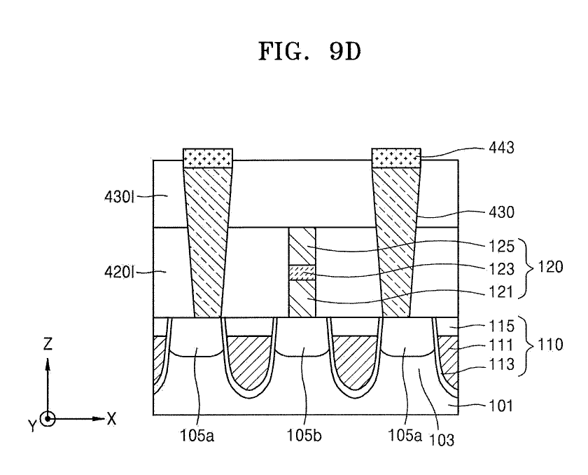

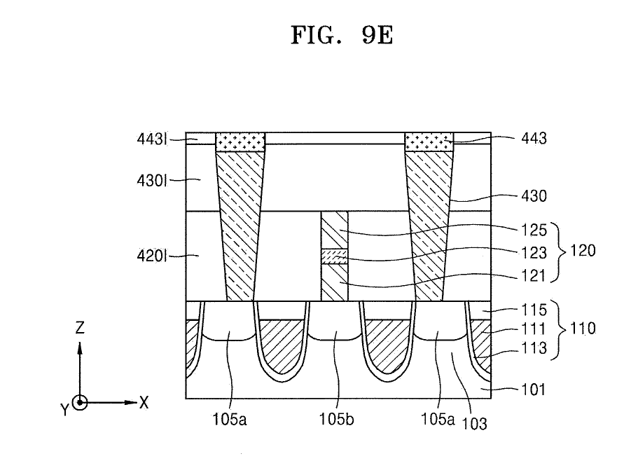

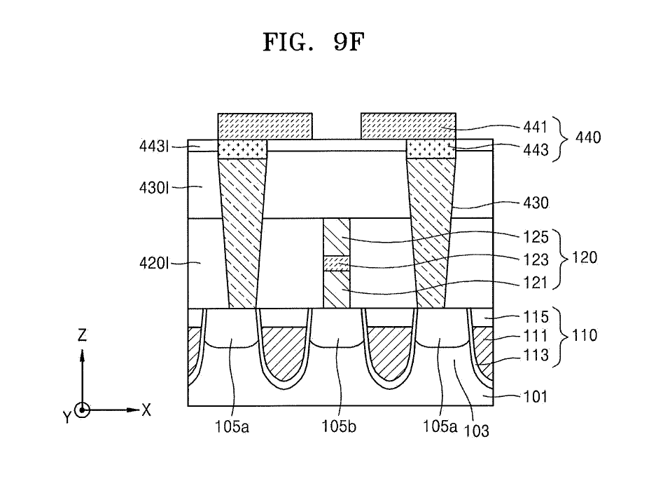

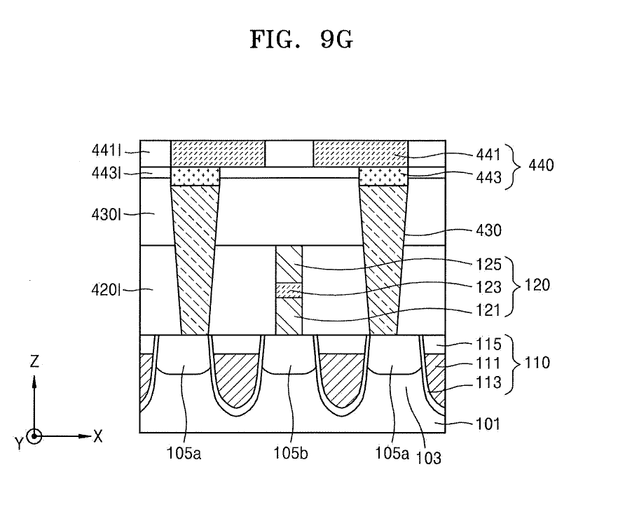

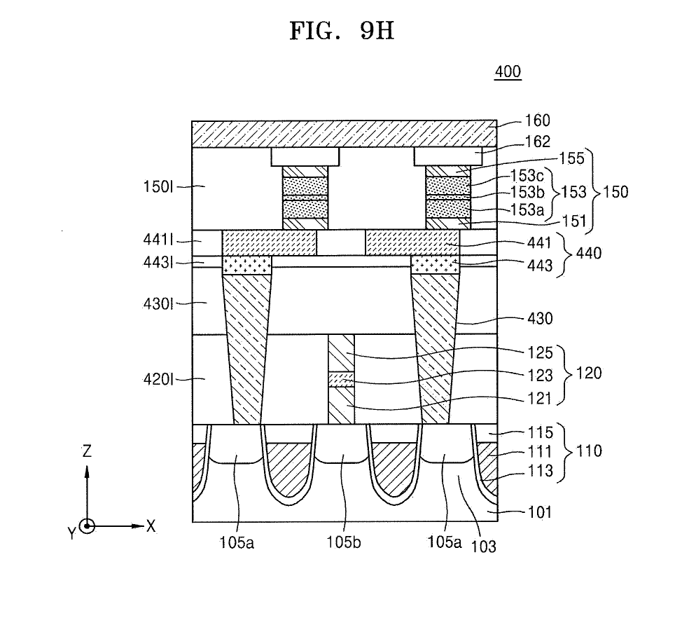

Referring to FIG. 5, the magnetic memory device 400 may include the word line structures 110, the source line structures 120, the first and second source/drain regions 105a and 105b, buried contacts 430, contact pads 440, the memory portions 150, the bit lines 160, first to fourth interlayer insulation layers 420I, 430I, 443I and 441I, and the fifth interlayer insulation layer 150I. A method of fabricating the magnetic memory device 400 will be described with reference to FIGS. 9A to 9H.

The buried contacts 430 may have a similar configuration to the buried contacts 330 described with reference to FIG. 4. For example, an upper width 430TW of each buried contact 430 in the first direction (i.e., the X-axis direction) may be greater than a lower width 430BW of each buried contact 430 in the first direction (i.e., the X-axis direction). Each of the buried contacts 430 may include, for example, a doped polysilicon material.

The contact pads 440 may be disposed on the buried contacts 430, respectively. Each of the contact pads 440 may include a buried metal silicide layer 443 and a metal pad 441, which are sequentially stacked.

The contact pads 440 may be electrically connected to the first source/drain regions 105a through the buried contacts 430, respectively.

The metal pad 441 may include a metal material and/or a conductive metal nitride material.

The buried metal silicide layer 443 may include the same material as the source metal silicide layer 123 described with reference to FIG. 2B. The buried metal silicide layer 443 may be disposed between the metal pad 441 and the buried contact 430 to reduce a contact resistance between the metal pad 441 and the buried contact 430.

As described above, if the upper width 430TW of each buried contact 430 in the first direction (i.e., the X-axis direction) is greater than the lower width 430BW of each buried contact 430 in the first direction (i.e., the X-axis direction) and the buried metal silicide layer 443 is disposed between the metal pad 441 and the buried contact 430, a planar area of the buried metal silicide layer 443 may increase as compared with a case that the buried metal silicide layer 443 is disposed in a middle portion of the buried contact 430, and an interfacial resistance of the buried metal silicide layer 443 may be reduced.

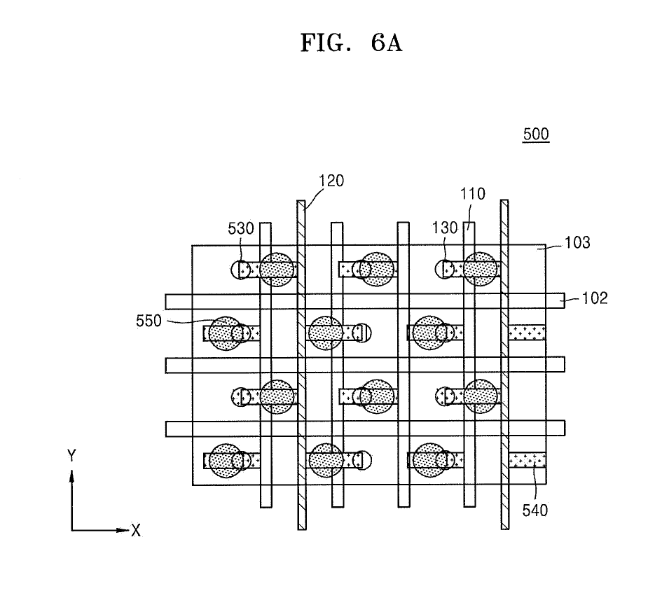

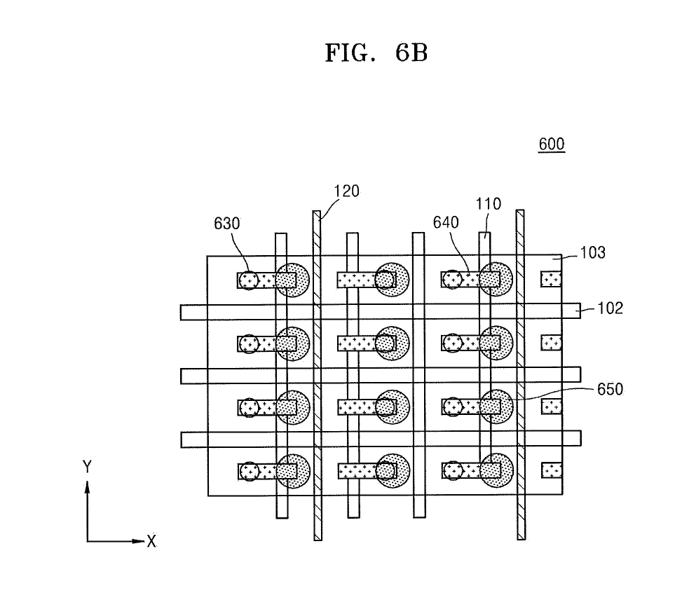

FIGS. 6A and 6B illustrate plan views of cell arrays of magnetic memory devices 500 and 600 according to other embodiments. In FIGS. 6A and 6B, the same reference numerals or the same reference designators as used in FIGS. 1 to 5 denote the same elements, and descriptions of the same components as set forth in the previous embodiments will be omitted or briefly mentioned in this embodiment to avoid duplicate explanation.

Referring to FIGS. 6A and 6B, each of the magnetic memory devices 500 and 600 may include the word line structures 110, the first and second source/drain regions 105a and 105b, the source line structures 120, buried contacts 530 or 630, contact pads 540 or 640, and memory portions 550 or 650.

Each of the buried contacts 530 may have a similar cross-sectional structure to one of the buried contacts 130, 330, and 430 described with reference to FIGS. 2B, 3, 4, and 5. Each of the buried contacts 630 may also have a similar cross-sectional structure to one of the buried contacts 130, 330, and 430 described with reference to FIGS. 2B, 3, 4, and 5.

In some embodiments, the contact pads 540 may have a similar structure to the contact pads 140 described with reference to FIGS. 2A and 2B. For example, each of the contact pads 540 may include the polysilicon pad 141 and the pad metal silicide layer 143. The contact pads 640 may also have a similar structure to the contact pads 140 described with reference to FIGS. 2A and 2B. For example, each of the contact pads 640 may include the polysilicon pad 141 and the pad metal silicide layer 143. In an embodiment, the contact pads 540 may have a similar structure to the contact pads 440 described with reference to FIG. 5. For example, each of the contact pads 540 may include the metal pad 441 and the buried metal silicide layer 443. The contact pads 640 may also have a similar structure to the contact pads 440 described with reference to FIG. 5. For example, each of the contact pads 640 may include the metal pad 441 and the buried metal silicide layer 443.

The buried contacts 530 (or 630) may be electrically connected to the memory portions 550 (or 650) through the contact pads 540 (or 640). Array structures of the buried contacts 530 (or 630), the memory portions 550 (or 650), and the contact pads 540 (or 640) may differ depending on the embodiments.

For example, as illustrated in FIG. 6A, the buried contacts 530 may be arrayed in a matrix form such that central points of the buried contacts 530 are located on horizontal straight lines extending in the first direction (i.e., the X-axis direction) and vertical straight lines extending in the second direction (i.e., the Y-axis direction). The memory portions 550 may be arrayed on horizontal straight lines extending in the first direction (i.e., the X-axis direction) and may be arrayed in a zigzag fashion along the second direction (i.e., the Y-axis direction). Similarly, the contact pads 540 may be arrayed on horizontal straight lines extending in the first direction (i.e., the X-axis direction) and may be arrayed in a zigzag fashion along the second direction (i.e., the Y-axis direction).

According to other embodiments, as illustrated in FIG. 6B, the buried contacts 630 may be arrayed in a matrix form such that central points of the buried contacts 630 are located on horizontal straight lines extending in the first direction (i.e., the X-axis direction) and vertical straight lines extending in the second direction (i.e., the Y-axis direction). Similarly, the memory portions 650 may be arrayed in a matrix form such that central points of the memory portions 650 are located on horizontal straight lines extending in the first direction (i.e., the X-axis direction) and vertical straight lines extending in the second direction (i.e., the Y-axis direction), and the contact pads 640 may be arrayed in a matrix form such that central points of the contact pads 640 are located on horizontal straight lines extending in the first direction (i.e., the X-axis direction) and vertical straight lines extending in the second direction (i.e., the Y-axis direction).

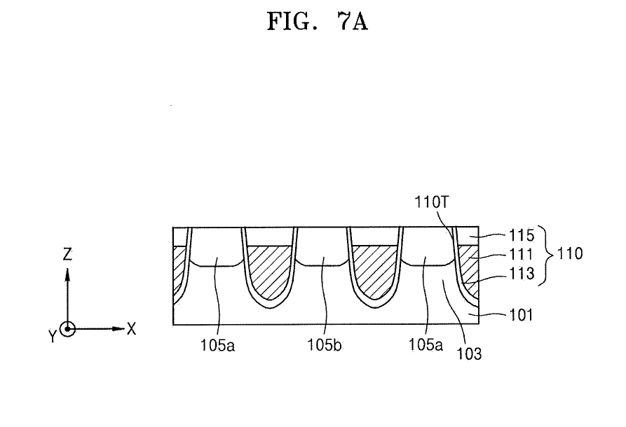

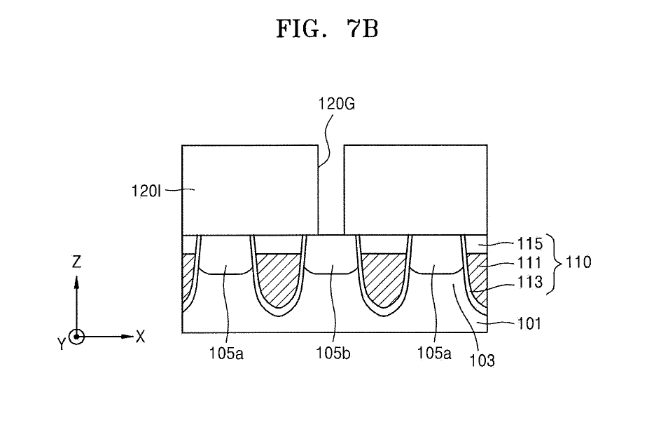

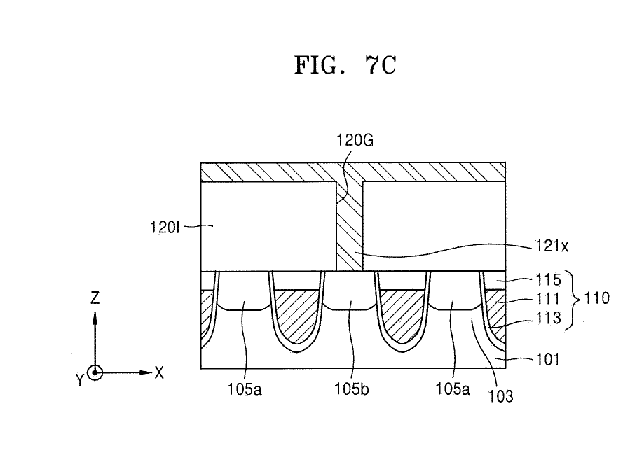

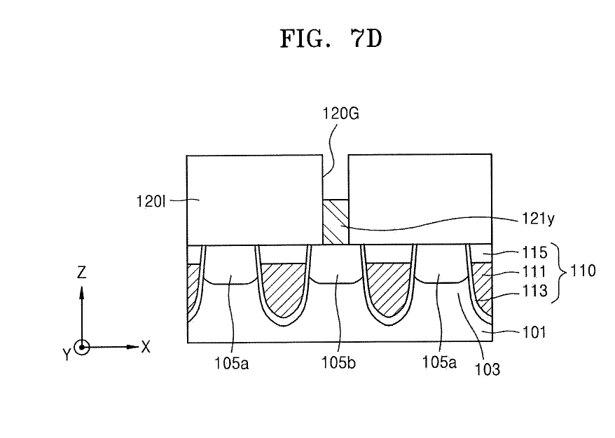

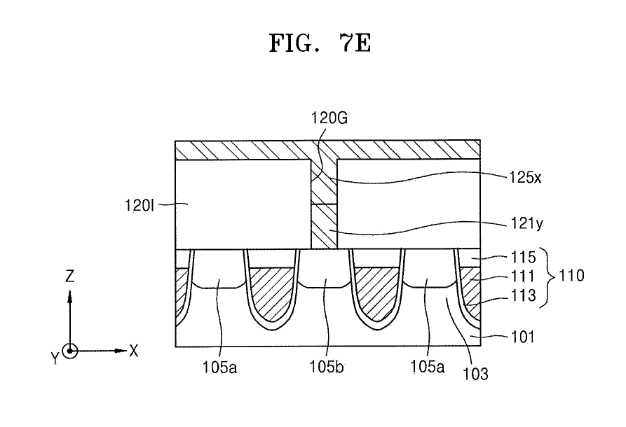

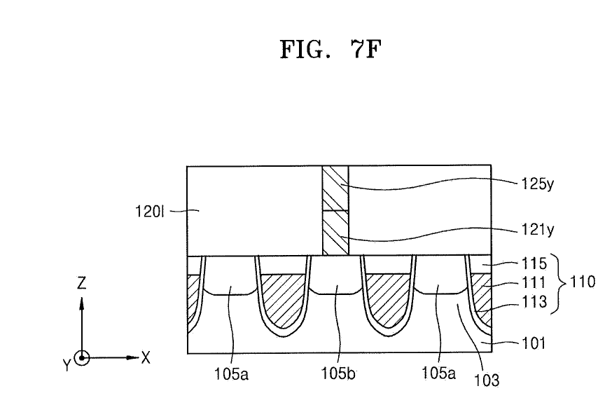

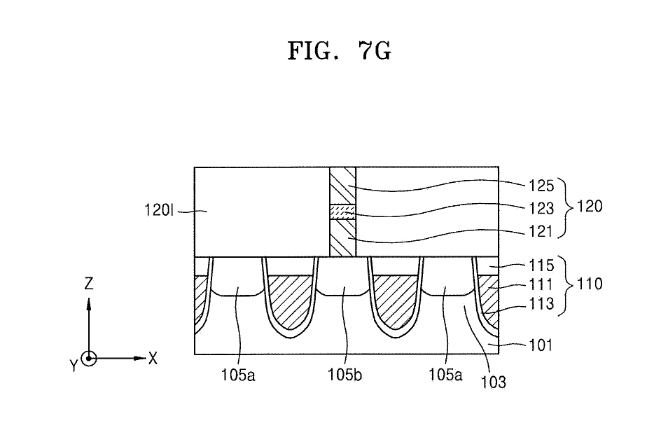

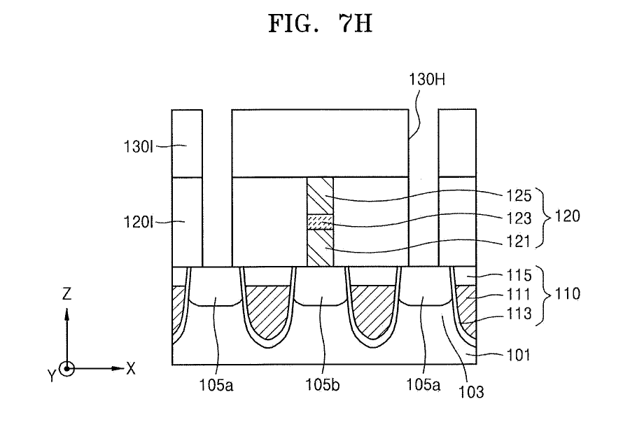

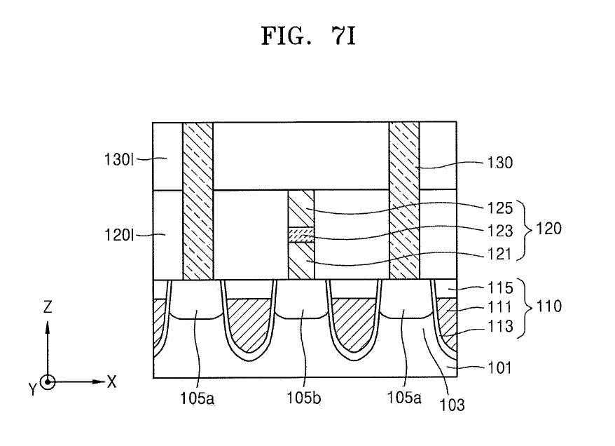

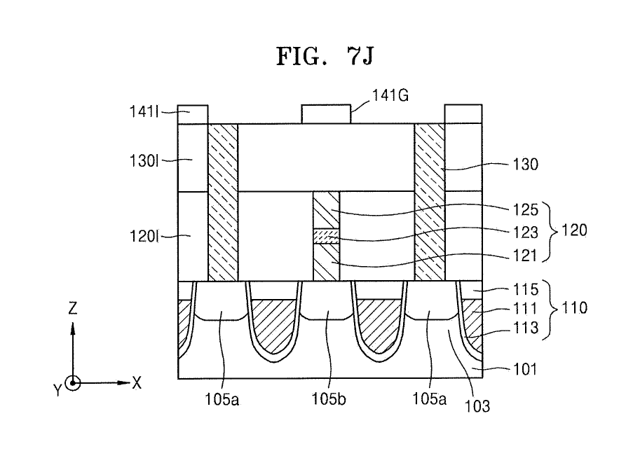

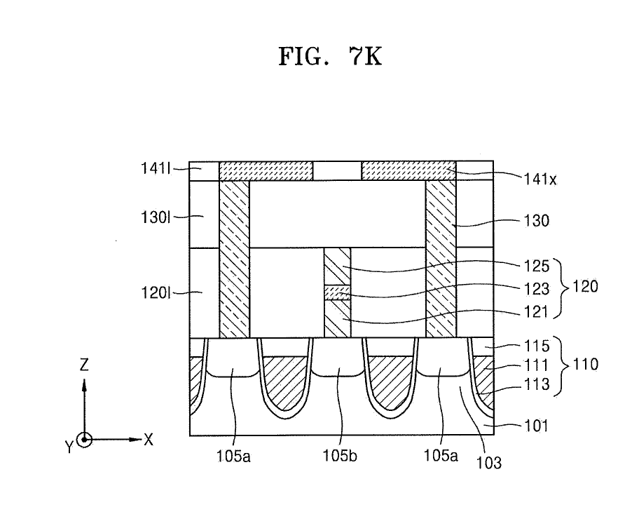

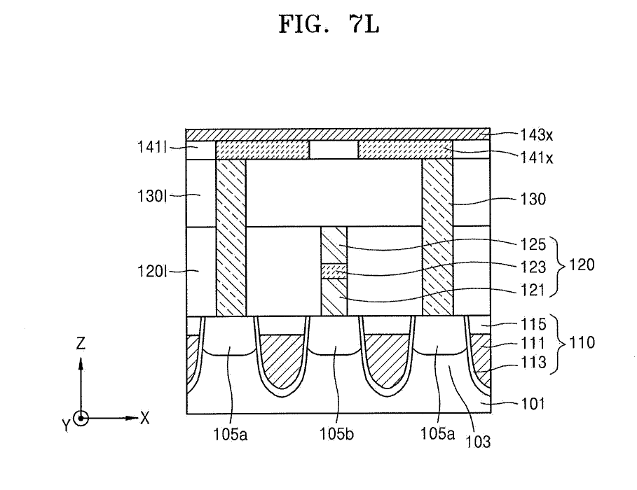

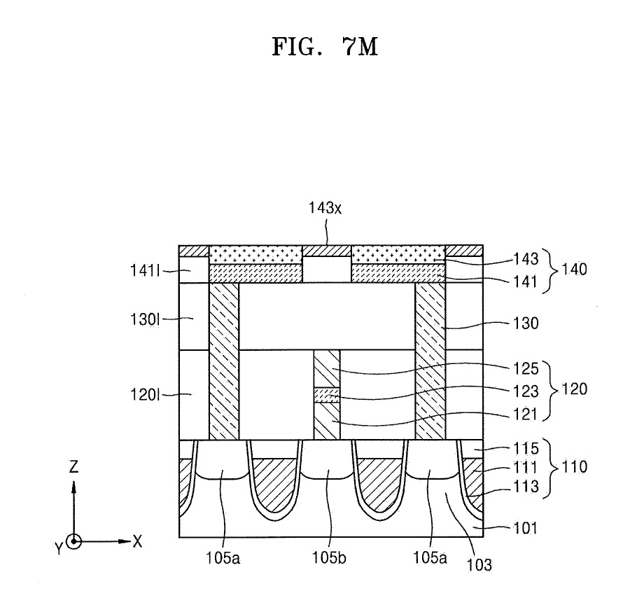

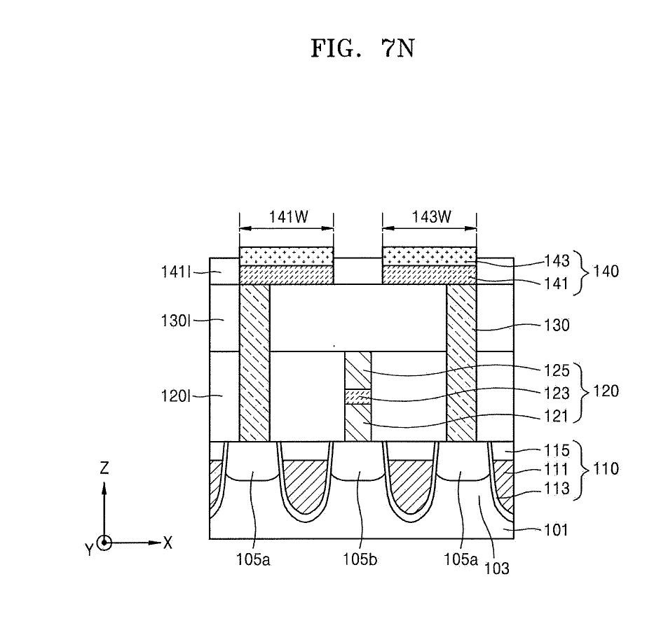

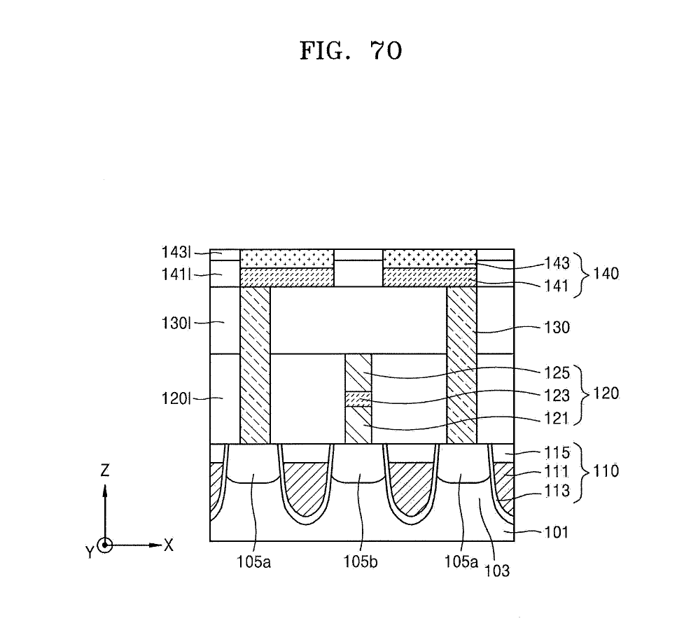

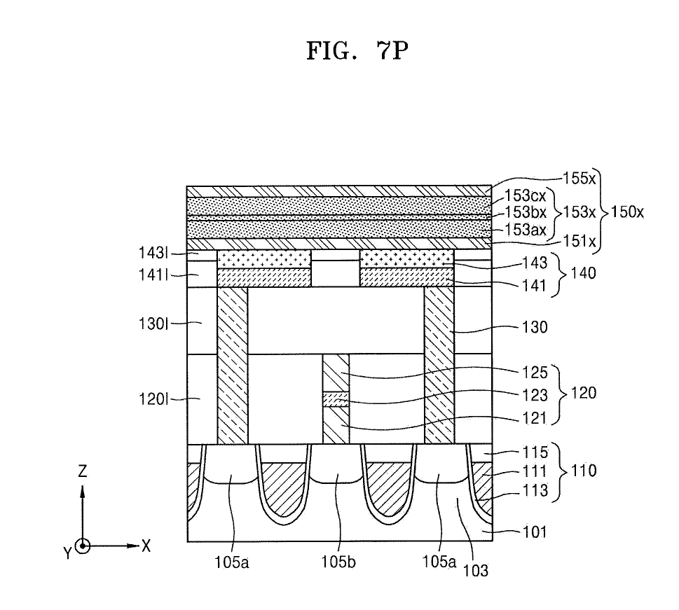

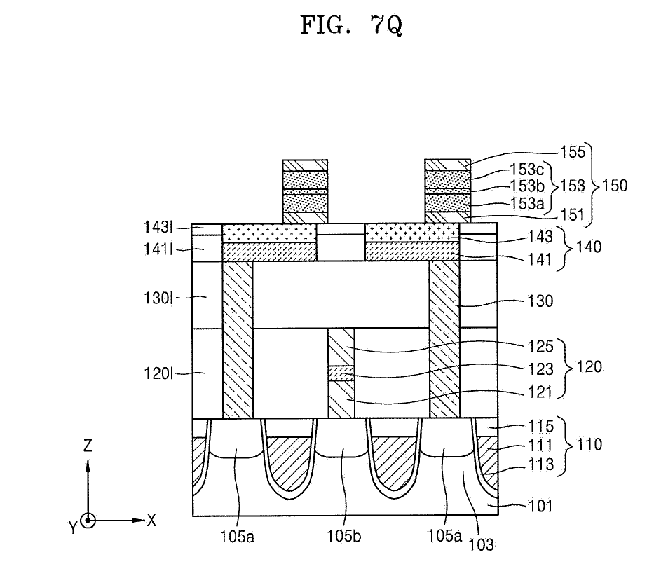

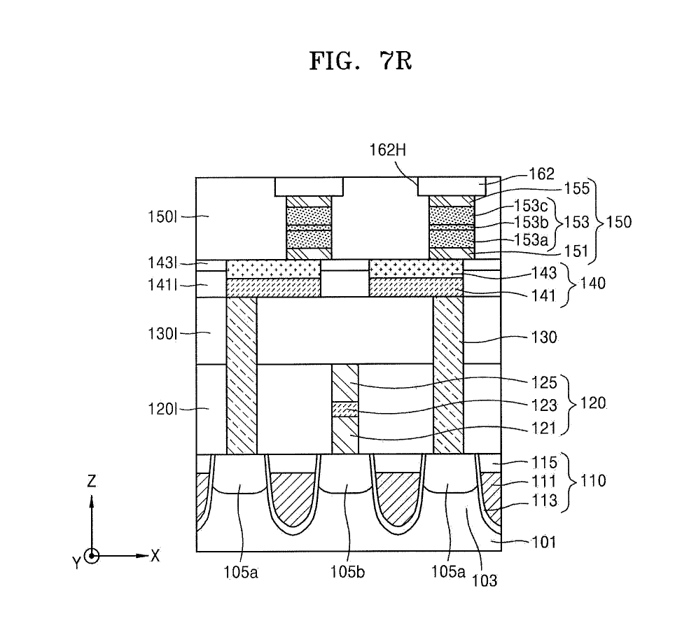

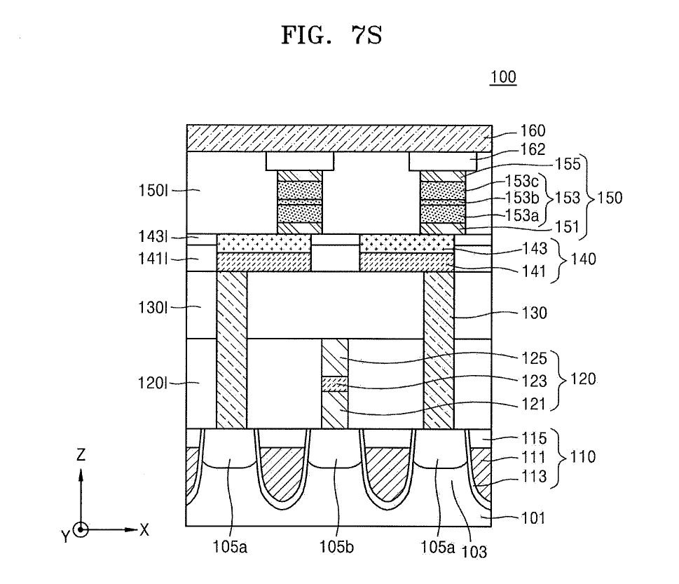

FIGS. 7A to 7S illustrate cross-sectional views of a method of fabricating a magnetic memory device, according to an embodiment. In FIGS. 7A to 7S, the same reference numerals or the same reference designators as used in FIGS. 1 to 5 denote the same elements, and the same descriptions as set forth in the previous embodiments illustrated in FIGS. 1 to 5 will be omitted or briefly mentioned in this embodiment to avoid duplicate explanation.

Referring to FIG. 7A, isolation layers (102 of FIG. 2A) may be formed in a substrate 101 to define active regions 103, and first and second source/drain regions 105a and 105b and word line structures 110 may be formed in the active regions 103 and in the substrate 101.

The isolation layers may be a silicon oxide layer, a silicon nitride layer, or a combination thereof. In some embodiments, the isolation layers may be formed of a single-layered insulation layer or a multi-layered insulation layer.

Now, processes for forming the first and second source/drain regions 105a and 105b and the word line structures 110 will be described hereinafter.

First, a mask pattern (not shown) may be formed on the substrate 101 by using a photolithography process. The substrate 101 may be etched using the mask pattern as an etch mask to form a plurality of gate trenches 110T in the substrate 101.

The plurality of gate trenches 110T may be arrayed in a first direction (i.e., an X-axis direction). The plurality of gate trenches 110T may extend in a second direction (i.e., a Y-axis direction) perpendicular to the first direction and have linear shapes, and the plurality of gate trenches 110T may be parallel with each other.

After the substrate 101 including the gate trenches 110T is cleaned, a gate dielectric layer 113, a word line 111, and a mask insulation layer 115 may be sequentially formed in each of the gate trenches 110T. The gate dielectric layer 113, the word line 111, and the mask insulation layer 115 formed in each gate trench 110T may constitute one of the word line structures 110.

Impurity ions may be implanted into the active regions 103 by using the word line structures 110 as ion implantation masks, thereby forming the first and second source/drain regions 105a and 105b. In some embodiments, the impurity ion implantation process for forming the first and second source/drain regions 105a and 105b may be performed before the gate trenches 110T are formed.

The word lines 111 may be formed of, for example, one or more of a polysilicon material, a titanium (Ti) material, a titanium nitride (TiN) material, a tantalum (Ta) material, a tantalum nitride (TaN) material, a tungsten (W) material, a tungsten nitride (WN) material, a titanium silicon nitride (TiSiN) material, or a tungsten silicon nitride (WSiN) material.

The gate dielectric layer 113 may be formed of one or more of a silicon oxide material, a silicon nitride material, a silicon oxynitride material, an oxide/nitride/oxide (ONO) material, or a high-k dielectric material having a higher dielectric constant than a silicon oxide material. For example, the gate dielectric layer 113 may be formed of a material having a dielectric constant of about 10 to about 25. In some embodiments, the gate dielectric layer 113 may be formed of one or more of a hafnium oxide (HfO) material, a hafnium silicon oxide (HfSiO) material, a hafnium oxynitride (HfON) material, a hafnium silicon oxynitride (HfSiON) material, a lanthanum oxide (LaO) material, a lanthanum aluminum oxide (LaAlO) material, a zirconium oxide (ZrO) material, a zirconium silicon oxide (ZrSiO) material, a zirconium oxynitride (ZrON) material, a zirconium silicon oxynitride (ZrSiON) material, a tantalum oxide (TaO) material, a titanium oxide (TiO) material, a barium strontium titanium oxide (BaSrTiO) material, a barium titanium oxide (BaTiO) material, a strontium titanium oxide (SrTiO) material, an yttrium oxide (YO) material, an aluminum oxide (AlO) material, or a lead scandium tantalum oxide (PbScTaO) material.

The mask insulation layer 115 may be formed of one or more of a silicon nitride material, a silicon oxide material, or a silicon oxynitride material.

Referring to FIG. 7B, a first interlayer insulation layer 120I having openings 120G may be formed on the substrate 101 including the first and second source/drain regions 105a and 105b and the word line structures 110.

The openings 120G may penetrate the first interlayer insulation layer 120I to expose the second source/drain regions 105b. In some embodiments, each of the openings 120G may be formed to extend in the second direction (i.e., the Y-axis direction). The openings 120G may intersect the isolation layers 102 to expose portions of the isolation layers 102 as well as the second source/drain regions 105b. The first interlayer insulation layer 120I may be a silicon oxide layer, a silicon nitride layer, or a combination thereof. For example, the first interlayer insulation layer 120I may be a tetraethyl orthosilicate (TEOS) layer or a high density plasma (HDP) oxide layer

Referring to FIG. 7C, a source line contact layer 121x may be formed on the first interlayer insulation layer 120I to fill the openings 120G. The source line contact layer 121x may be formed of, for example, a doped polysilicon material.

Referring to FIG. 7D, after the source line contact layer 121x is formed, the source line contact layer 121x may be etched back to form source line contact patterns 121y in the openings 120G, and the source line contact patterns 121y may be formed to partially fill the openings 120G.

Referring to FIG. 7E, a source line layer 125x may be formed on the first interlayer insulation layer 120I to fill the openings 120G and be on the source line contact patterns 121y. The source line layer 125x may be formed to include a metal layer or a conductive metal nitride layer. In some embodiments, the source line layer 125x may be formed of a single-layered material layer or a multi-layered material layer. For example, the source line layer 125x may be formed by sequentially stacking a titanium (Ti) layer, a titanium nitride (TiN) layer, and a tungsten (W) layer.

Referring to FIG. 7F, the source line layer 125x may be planarized using a chemical mechanical polishing (CMP) process until a top surface of the first interlayer insulation layer 120I is exposed, thereby forming source line patterns 125y in the openings 120G.

Referring to FIG. 7G, a first silicidation process may performed on the substrate 101 having the source line contact patterns 121y and the source line patterns 125y to form source line structures 120, each of which includes a source line contact 121, a source metal silicide layer 123, and a source line 125.

The source metal silicide layer 123 may be formed by a chemical reaction of the source line contact pattern 121y and the source line pattern 125y in each opening 120G during the first silicidation process.

For example, if the source line pattern 125y includes a titanium (Ti) layer, a titanium nitride (TiN) layer, and a tungsten (W) layer, which are sequentially stacked, and the source line contact 121y includes a polysilicon layer, the source metal silicide layer 123 may be a titanium silicide (TiSi) layer which is formed by a chemical reaction of the titanium (Ti) layer and the polysilicon layer.

The first silicidation process may be performed by annealing the substrate 101, including the source line contact patterns 121y and the source line patterns 125y, in a furnace. In some embodiments, the first silicidation process may be performed using a rapid thermal process (RTP).

The first silicidation process may include at least one annealing process or operation. For example, the first silicidation process may include a first annealing process that is performed at a temperature of about 250 degrees Celsius to about 550 degrees Celsius and a second annealing process that is performed at a temperature of about 600 degrees Celsius to about 900 degrees Celsius after the first annealing process.

As described above, if the first silicidation process is performed using two annealing processes or operations (i.e., the first and second annealing processes), a resistivity of the source metal silicide layer 123 may be significantly reduced.

Referring to FIG. 7H, a second interlayer insulation layer 130I may be formed on the first interlayer insulation layer 120I and the source line structures 120. The second interlayer insulation layer 130I and the first interlayer insulation layer 120I may be patterned to form a plurality of contact holes 130H.

The second interlayer insulation layer 130I may be a silicon oxide layer, a silicon nitride layer, or a combination thereof. In some embodiments, the second interlayer insulation layer 130I may be the same material layer as the first interlayer insulation layer 120I.

The contact holes 130H may be formed by performing an etch process on the second interlayer insulation layer 130I and the first interlayer insulation layer 120I. The contact holes 130H may be formed to expose the first source/drain regions 105a.

Referring to FIG. 7I, buried contacts 130 may be respectively formed in the contact holes 130H, and each of the buried contacts 130 may be formed to penetrate the first and second interlayer insulation layers 120I and 130I and may be electrically connected to one of the first source/drain regions 105a. The buried contacts 130 may be formed of a doped polysilicon material.

Referring to FIG. 7J, a third interlayer insulation layer 141I may be formed on the second interlayer insulation layer 130I and the buried contacts 130. The third interlayer insulation layer 141I may be patterned to form a plurality of grooves 141G.

The third interlayer insulation layer 141I may be a silicon oxide layer, a silicon nitride layer, or a combination thereof. In some embodiments, the third interlayer insulation layer 130I may be the same material layer as the first or second interlayer insulation layer 120I or 130I.

The grooves 141G may be formed by performing an etch process on the third interlayer insulation layer 141I. Each of the grooves 141G may be formed to expose one of the buried contacts 130 and a portion of the second interlayer insulation layer 130I.

Referring to FIG. 7K, polysilicon pad patterns 141x may be formed in the grooves 141G, respectively, and the polysilicon pad patterns 141x may be electrically connected to the buried contacts 130. A width of each polysilicon pad pattern 141x in the first direction (i.e., the X-axis direction) may be greater than a width of each polysilicon pad pattern 141x in the second direction (i.e., the Y-axis direction).

The polysilicon pad patterns 141x may be formed of a doped polysilicon material.

If the polysilicon pad patterns 141x are formed of a doped polysilicon material, the third interlayer insulation layer 141I may be formed of a silicon oxide layer, and the third interlayer insulation layer 141I may be formed using a low temperature deposition process. As a result, a heat budget may be alleviated while the third interlayer insulation layer 141I is formed, the polysilicon pad patterns 141x may be formed using a damascene process, and the processes for forming the third interlayer insulation layer 141I and contact pads (140 of FIG. 7M) may be more readily performed.

Referring to FIG. 7L, a metal layer 143x may be formed on the third interlayer insulation layer 141I and the polysilicon pad patterns 141x.

The metal layer 143x may be formed of a metal material that can react with a silicon material to form a metal silicide layer. For example, the metal layer 143x may be formed of one or more of a cobalt (Co) material, a titanium (Ti) material, a tantalum (Ta) material, a tungsten (W) material, a nickel (Ni) material, a platinum (Pt) material, or an alloy material thereof.

The metal layer 143x may be formed using a physical vapour deposition (PVD) process, a chemical vapour deposition (CVD) process, or an atomic layer deposition (ALD) process. The PVD process may correspond to a sputtering process.

Referring to FIG. 7M, pad metal silicide layers 143 may be formed.

The pad metal silicide layers 143 may be formed by performing a second silicidation process on the metal layer 143x and the polysilicon pad patterns 141x.

For example, the pad metal silicide layers 143 may be formed by a chemical reaction of the metal layer 143x and the polysilicon pad patterns 141x during the second silicidation process.

For example, if the metal layer 143x is formed of a cobalt (Co) material, the pad metal silicide layers 143 may be cobalt silicide (CoSi) layers which are formed by a chemical reaction of the cobalt (Co) material and the polysilicon pad patterns 141x.

The second silicidation process may be performed by annealing the metal layer 143x in a furnace. In some embodiments, the second silicidation process may be performed using a rapid thermal process (RTP).

The second silicidation process may include a first annealing process that is performed at a temperature of about 250 degrees Celsius to about 550 degrees Celsius and a second annealing process that is performed at a temperature of about 600 degrees Celsius to about 900 degrees Celsius after the first annealing process.

Referring to FIG. 7N, an unreacted metal layer 143x remaining on the third interlayer insulation layer 141I may be removed. The unreacted metal layer 143x may be removed using a wet etch process.

In some embodiments, the unreacted metal layer 143x may be removed after the first and second annealing processes are performed. In an embodiment, the unreacted metal layer 143x may be removed after the first annealing process but before the second annealing process.

As a result of the removal of the unreacted metal layer 143x, contact pads 140 may be formed on the buried contacts 130. Each of the contact pads 140 may be formed to include a polysilicon pad 141 and a pad metal silicide layer 143, which are sequentially stacked.

A width 143W of each pad metal silicide layer 143 in the first direction (i.e., the X-axis direction) may be substantially equal to a width 141W of each polysilicon pad 141 in the first direction (i.e., the X-axis direction).

As illustrated in FIG. 2A, the contact pads 140 may be arrayed in a matrix form such that central points of the contact pads 140 are located on straight lines extending in the first direction (i.e., the X-axis direction) and straight lines extending in the second direction (i.e., the Y-axis direction) in a plan view. In an embodiment, the contact pads 140 may be arrayed on horizontal straight lines extending in the first direction (i.e., the X-axis direction) and may be arrayed in a zigzag fashion along the second direction (i.e., the Y-axis direction).

Referring to FIG. 7O, a fourth interlayer insulation layer 143I may be formed on the third interlayer insulation layer 141I to cover sidewalls of the pad metal silicide layers 143.

The fourth interlayer insulation layer 143I may be formed of a silicon oxide material, a silicon nitride material, or a combination thereof.

In some embodiments, the fourth interlayer insulation layer 143I may be formed of the same material as one or more of the first, second or third interlayer insulation layers 120I, 130I, or 141I.

The fourth interlayer insulation layer 143I may be formed by depositing an insulation layer (not shown) on the third interlayer insulation layer 141I to cover the contact pads 140 and by planarizing the insulation layer with a CMP process to expose top surfaces of the pad metal silicide layers 143.

Referring to FIG. 7P, a bottom electrode layer 151x, an MTJ layer 153x, and a top electrode layer 155x may be sequentially formed on the fourth interlayer insulation layer 143I and the contact pads 140. The bottom electrode layer 151x, the MTJ layer 153x, and the top electrode layer 155x may constitute a memory portion layer 150x.

The bottom electrode layer 151x may be formed of a metal or a metal nitride, and the top electrode layer 155x may also be formed of include a metal or a metal nitride. For example, each of the bottom electrode layer 151x and the top electrode layer 155x may be formed of one or more of a tantalum (Ta) material, an aluminum (Al), a copper (Cu) material, a gold (Au) material, a titanium (Ti) material, a tantalum nitride (TaN) material, or a titanium nitride (TiN) material. The bottom electrode layer 151x and the top electrode layer 155x may be formed using a CVD process, a PVD process, an ALD process, or a pulsed laser deposition (PLD) process.

The MTJ layer 153x may be formed to have a multi-layered structure including a pinned magnetic layer 153ax, a free magnetic layer 153cx, and a tunnel barrier layer 153bx disposed between the pinned magnetic layer 153ax and the free magnetic layer 153cx.

The pinned magnetic layer 153ax may be formed of a ferromagnetic material, for example, a cobalt-iron (CoFe) material, a nickel-iron (NiFe) material, or an iron-manganese (FeMn) material. The free magnetic layer 153cx may also be formed of a ferromagnetic material, for example, a cobalt-iron (CoFe) material, a nickel-iron (NiFe) material, or an iron-manganese (FeMn) material. The tunnel barrier layer 153bx may be formed of one or more of a magnesium oxide material, a titanium oxide material, an aluminum oxide material, a zinc magnesium oxide material, or a boron magnesium oxide material.

In some embodiments, the pinned magnetic layer 153ax, the free magnetic layer 153cx, and the tunnel barrier layer 153bx may be formed using a molecular beam epitaxy (MBE) process, a metal organic chemical vapor deposition (MOCVD) process, a direct current (DC) sputtering process, a radio frequency (RF) sputtering process, an ion beam sputtering process, a magnetron sputtering process, or an ultra-high vacuum (UHV) sputtering process.

Referring to FIG. 7Q, a plurality of conductive mask patterns (not shown) may be formed on the top electrode layer 155x, and the memory portion layer 150x may be etched using the conductive mask patterns as etch masks.

The conductive mask patterns may be formed of a metal material or a metal nitride material. In some embodiments, the conductive mask patterns may be formed of one or more of a ruthenium (Ru) material, a tungsten (W) material, a titanium nitride (TiN) material, a tantalum nitride (TaN) material, a titanium (Ti) material, a tantalum (Ta) material, or a metallic vitrified alloy. For example, the conductive mask patterns may be formed to have a double-layered structure such as a ruthenium/titanium nitride (Ru/TiN) material or a titanium nitride/tungsten (TiN/W) material.

The memory portion layer 150x may be patterned using a plasma etch process. In some embodiments, the memory portion layer 150x may be patterned using a reactive ion etching (RIE) process, an ion beam etching process, or an argon milling process. The etching process for patterning the memory portion layer 150x may be performed using SF₆ gas, NF₃ gas, SiF₄ gas, CF₄ gas, Cl₂ gas, CH₃OH gas, CH₄ gas, CO gas, NH₃ gas, H₂ gas, N₂ gas, HBr gas, or a combination thereof as a first etching gas. In some embodiments, a first additional gas, for example, one or more of Ne gas, Ar gas, Kr gas, or Xe gas may be additionally used together with the first etching gas to pattern the memory portion layer 150x. Moreover, the etching process for patterning the memory portion layer 150x may further include another etching process that is performed with a second etching gas having a different composition from the first etching gas. The second etching gas may include SF₆ gas, NF₃ gas, SiF₄ gas, CF₄ gas, Cl₂ gas, CH₃OH gas, CH₄ gas, CO gas, NH₃ gas, H₂ gas, N₂ gas, HBr gas, or a combination thereof. During the etching process performed with the second etching gas, a second additional gas, for example, one or more of Ne gas, Ar gas, Kr gas, or Xe gas may be additionally used together with the second etching gas to pattern the memory portion layer 150x.

The etching process for patterning the memory portion layer 150x may be performed using plasma which is generated by an inductively coupled plasma (ICP) source, a capacitively coupled plasma (CCP) source, an electron cyclotron resonance (ECR) plasma source, a helicon-wave excited plasma (HWEP) source, or a adaptively coupled plasma (ACP) source.

The etching process for patterning the memory portion layer 150x may be performed at a temperature of about 10 degrees Celsius below zero to about 65 degrees Celsius and under a pressure of about 2 mTorr to about 5 mTorr.

As a result of the etching process for patterning the memory portion layer 150x, a plurality of memory portions 150 may be formed on respective ones of the contact pads 140. Each of the memory portions 150 may be formed to include a bottom electrode 151, an MTJ element 153 and a top electrode 155. The MTJ element 153 may be formed to include a pinned layer 153a connected to the bottom electrode 151, a free layer 153c connected to the top electrode 155, and a tunnel barrier layer 153b disposed between the pinned layer 153a and the free layer 153c.

Referring to FIG. 7R, a fifth interlayer insulation layer 150I may be formed on the fourth interlayer insulation layer 143I and the memory portions 150, and the fifth interlayer insulation layer 150I may be planarized and etched to form bit line contact holes 162H exposing top surfaces of the memory portions 150. Subsequently, a conductive layer may be formed on the fifth interlayer insulation layer 150I to fill the bit line contact holes 162H, and the conductive layer may be planarized or etched back to expose a top surface of the fifth interlayer insulation layer 150I and to form bit line contacts 162 in the bit line contact holes 162H, respectively.

Referring to FIG. 7S, a conductive layer may be formed on the fifth interlayer insulation layer 150I and the bit line contacts 162, the conductive layer may be patterned to form line-shaped bit lines 160, which are electrically connected to the bit line contacts 162, and the magnetic memory device 100 may be formed.

FIGS. 8A, 8B, and 8C illustrate cross-sectional views of a method of fabricating the magnetic memory device 200 shown in FIG. 3. In FIGS. 8A, 8B, and 8C, the same reference numerals or the same reference designators as used in FIGS. 1 to 5 and 7A to 7S denote the same elements, and the same descriptions as set forth in the previous embodiments illustrated in FIGS. 1 to 5 and 7A to 7S will be omitted or briefly mentioned in this embodiment to avoid duplicate explanation.

This embodiment may be similar to the previous embodiment described with reference to FIGS. 7A to 7S. This embodiment may differ from the embodiment described with reference to FIGS. 7A to 7S in terms of a method of etching the memory portion layer 150x, and differences between this embodiment and the previous embodiment illustrated in FIGS. 7A to 7S will be mainly described hereinafter.

Referring to FIG. 8A, the word line structures 110, the first and second source/drain regions 105a and 105b, the source line structures 120, the buried contacts 130, the contact pads 140, and the memory portion layer 150x may be formed on the substrate 101 in the same manner as described with reference to FIGS. 7A to 7P.

Referring to FIG. 8B, the memory portion layer 150x may be etched to form the memory portions 150. The etching process for forming the memory portions 150 in this embodiment may be similar to the etching process for forming the memory portions 150, which is described with reference to FIG. 7Q.

Unlike the etching process described with reference to FIG. 7Q, the etching process in this embodiment may be performed to etch at least one of the third and fourth interlayer insulation layers 141I and 143I by a predetermined thickness. For example, an over-etching process may be performed on the memory portion layer 150x such that an end point of the over-etching process for forming the memory portions 150 may be lower than top surfaces 143T of the pad metal silicide layers 143.

As a result of the over-etching process for forming the memory portions 150, the over-etched fourth interlayer insulation layer 243I may remain only under a portion of each of the memory portions 150. For example, the remaining portions of the over-etched fourth interlayer insulation layer 243I may vertically overlap with edges of the memory portions 150. A top surface 241IT of the over-etched third interlayer insulation layer 241I may have stepped profiles. For example, the over-etched third interlayer insulation layer 241I may include overlap regions vertically overlapping with the memory portions 150 and a non-overlap region having a top surface which is at a lower level than top surfaces of the overlap regions thereof.

As described with reference to FIG. 3, the pad metal silicide layers 143 may function as etch stop layers while the over-etching process for forming the memory portions 150 is performed. During the over-etching process for forming the memory portions 150, the pad metal silicide layers 143 may prevent the contact pads 140 from being deformed or damaged, and the over-etching process for forming the memory portions 150 may be more readily or stably performed.

Referring to FIG. 8C, a fifth interlayer insulation layer 250I, the bit lines contacts 162, and the bit lines 160 may be formed to realize the magnetic memory device 200.

The fifth interlayer insulation layer 250I, the bit lines contacts 162, and the bit lines 160 may be formed similarly as described with reference to FIGS. 7R and 7S.

FIGS. 9A to 9H illustrate cross-sectional views of a method of fabricating the magnetic memory device 400 shown in FIG. 5. In FIGS. 9A to 9H, the same reference numerals or the same reference designators as used in FIGS. 1 to 5 and 7A to 7S denote the same elements, and the same descriptions as set forth in the previous embodiments illustrated in FIGS. 1 TO 5 and 7A to 7S will be omitted or briefly mentioned in this embodiment to avoid duplicate explanation.

This embodiment may be similar to the previous embodiment described with reference to FIGS. 7A to 7S. This embodiment may differ from the embodiment described with reference to FIGS. 7A to 7S in terms of structures of buried contacts 430 and contact pads 440 as well as fabrication methods thereof, and differences between this embodiment and the previous embodiment illustrated in FIGS. 7A to 7S will be mainly described hereinafter.

Referring to FIG. 9A, the word line structures 110, the first and second source/drain regions 105a and 105b, the source line structures 120, the buried contacts 430, and first and second interlayer insulation layers 420I and 430I may be formed on the substrate 101 similarly as described with reference to FIGS. 7A to 71.

For example, the buried contacts 430 may be formed similarly as fabrication methods of the buried contacts 130 described with reference to FIGS. 7A to 71, and the first and second interlayer insulation layers 420I and 430I may be formed similarly as fabrication methods of the first and second interlayer insulation layers 120I and 130I described with reference to FIGS. 7A to 71.

Unlike the buried contacts 130 described with reference to FIG. 7I, the buried contacts 430 may be formed such that an upper width 430TW of each buried contact 430 in the first direction (i.e., the X-axis direction) is greater than a lower width 430BW of each buried contact 430 in the first direction (i.e., the X-axis direction).

Referring to FIG. 9B, a metal layer 443x may be formed on the second interlayer insulation layer 430I and the buried contacts 430. The metal layer 443x may be formed of a metal material that can react with a silicon material to form a metal silicide layer and may be formed using a PVD process or CVD process, like the metal layer 143x described with reference to FIG. 7I.

Referring to FIG. 9C, buried metal silicide layers 443 may be selectively formed on the buried contacts 430, respectively.

The buried metal silicide layers 443 may be formed similar to the formation method of the pad metal silicide layers 143 described with reference to FIG. 7M.

In some embodiments, a width 443W of each buried metal silicide layer 443 in the first direction (i.e., the X-axis direction) may be substantially equal to the upper width 430TW of each buried contact 430 in the first direction (i.e., the X-axis direction).

A planar area of each buried metal silicide layer 443 may be maximized to reduce an interfacial resistance of each of the buried metal silicide layers 443.

Referring to FIG. 9D, an unreacted metal layer 443x remaining on the second interlayer insulation layer 430I may be removed.

The unreacted metal layer 443x may be removed similar to the removal method of the unreacted metal layer 143x described with reference to FIG. 7N.

Referring to FIG. 9E, a third interlayer insulation layer 443I may be formed on the second interlayer insulation layer 430I to cover sidewalls of the buried metal silicide layers 443. The third interlayer insulation layer 443I may be formed of a silicon oxide material, a silicon nitride material, or a combination thereof.

The third interlayer insulation layer 443I may be formed by depositing an insulation layer (not shown) on the second interlayer insulation layer 430I to cover the buried metal silicide layers 443 and by planarizing the insulation layer with a CMP process to expose top surfaces of the buried metal silicide layers 443.

Referring to FIG. 9F, metal pads 441 may be formed on the buried metal silicide layers 443 and the third interlayer insulation layer 443I.

For example, a metal layer may be formed on the buried metal silicide layers 443 and the third interlayer insulation layer 443I, and the metal layer may be patterned to form the metal pads 441.

The metal pads 441 may be formed of, for example, a metal and/or a conductive metal nitride. The metal pad 441 and the buried metal silicide layer 443 stacked on each buried contact 430 may constitute a contact pad 440.

Referring to FIG. 9G, a fourth interlayer insulation layer 441I may be formed on the third interlayer insulation layer 443I to cover the metal pads 441, and the fourth interlayer insulation layer 441I may be planarized to expose top surfaces of the metal pads 441. The fourth interlayer insulation layer 441I may be planarized using, for example, a CMP process.

Referring to FIG. 9H, the memory portions 150, the fifth interlayer insulation layer 150I, the bit line contacts 162, and the bit lines 160 may be formed on the metal pads 441 and the fourth interlayer insulation layer 441I to realize the magnetic memory device 400.

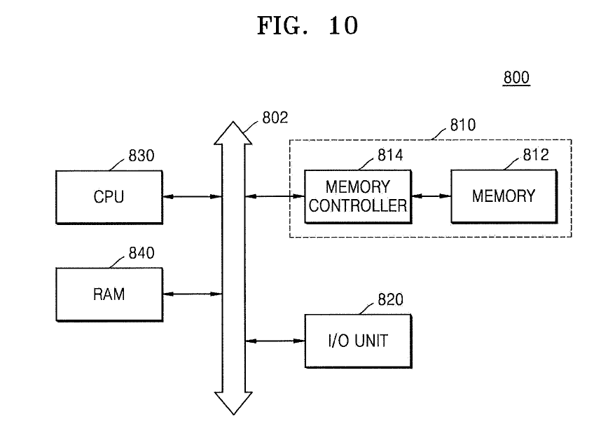

FIG. 10 illustrates a block diagram of an information processing system 800 including at least one magnetic memory device according to some embodiments.

Referring to FIG. 10, the information processing system 800 may include a nonvolatile memory system 810, an input/output (I/O) unit 820, a central processing unit (CPU) 830, and a random access memory (RAM) 840 that communicate with each other through a bus 802.

The nonvolatile memory system 810 may include a memory 812 and a memory controller 814. The nonvolatile memory system 810 may store data processed by the CPU 830 or data transmitted from an external system.

The nonvolatile memory system 810 may include a nonvolatile memory such as magnetic random access memory (MRAM), phase changeable random access memory (PRAM), resistive random access memory (RRAM), or ferroelectric random access memory (FRAM). At least one of the memory 812 and the RAM 840 may include the magnetic memory device 100, 200, 300, 400, 500, or 600 according to an embodiment.

The information processing system 800 may be applied to portable computers, web tablets, wireless phones, mobile phones, digital music players, memory cards, MP3 players, navigators, portable multimedia players (PMPs), solid state disks (SSDs), or household appliances.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A magnetic memory device, comprising:
a substrate including a first source/drain region and a second source/drain region;
a word line structure disposed between the first and second source/drain regions and extending in a first direction;
a buried contact electrically connected to the first source/drain region and disposed on the first source/drain region;
a contact pad electrically connected to the buried contact and disposed on the buried contact, the contact pad including a metal silicide layer; and
a memory portion electrically connected to the contact pad and disposed on the contact pad.

2. The magnetic memory device as claimed in claim 1, wherein the metal silicide layer includes one or more of a cobalt silicide layer, a titanium silicide layer, a tantalum silicide layer, a tungsten silicide layer, a nickel silicide layer, or a platinum silicide layer.

3. The magnetic memory device as claimed in claim 1, wherein a width of the metal silicide layer in a second direction perpendicular to the first direction is greater than a width of the buried contact in the second direction.

4. The magnetic memory device as claimed in claim 1, wherein:
the memory portion includes a bottom electrode, a magnetic tunnel junction element, and a top electrode, which are sequentially stacked; and
the magnetic tunnel junction element includes a pinned layer, a tunnel barrier layer, and a free layer.

5. The magnetic memory device as claimed in claim 1, wherein the buried contact includes a polysilicon material.

6. The magnetic memory device as claimed in claim 1, wherein the contact pad further includes a polysilicon pad.

7. The magnetic memory device as claimed in claim 6, wherein the polysilicon pad contacts the buried contact, and the metal silicide layer contacts the memory portion.

8. The magnetic memory device as claimed in claim 7, wherein a width of the polysilicon pad in a second direction perpendicular to the first direction is substantially equal to a width of the metal silicide layer in the second direction.

9. The magnetic memory device as claimed in claim 1, wherein the contact pad further includes a metal pad.

10. The magnetic memory device as claimed in claim 9, wherein the metal silicide layer contacts the buried contact, and the metal pad contacts the memory portion.

11. The magnetic memory device as claimed in claim 1, further comprising a source line structure electrically connected to the second source/drain region and extending in the first direction,
wherein the source line structure includes a source line contact contacting the second source/drain region, a source metal silicide layer on the source line contact, and a source line on the source metal silicide layer.

12. A magnetic memory device, comprising:
a substrate including an active region defined by an isolation layer;
a first source/drain region and a second source/drain region in the active region;
a word line structure disposed between the first and source/drain regions and extending in a first direction;
a buried contact disposed on the first source/drain region and electrically connected to the first source/drain region, the buried contact including a polysilicon material;
a contact pad disposed on the buried contact and electrically connected to the buried contact, the contact pad including a polysilicon pad and a first metal silicide layer, which are sequentially stacked;
a memory portion disposed on the first metal silicide layer and electrically connected to the contact pad;
a source line structure disposed on the second source/drain region and electrically connected to the second source/drain region; and
a bit line extending in a second direction perpendicular to the first direction and electrically connected to the memory portion.

13. The magnetic memory device as claimed in claim 12, wherein a width of the polysilicon pad in the second direction is substantially equal to a width of the first metal silicide layer in the second direction.

14. The magnetic memory device as claimed in claim 12, wherein:
the source line structure includes a source line contact contacting the second source/drain region, a second metal silicide layer on the source line contact, and a source line on the second metal silicide layer; and
a width of the first metal silicide layer in the second direction is greater than a width of the second metal silicide layer in the second direction.

15. The magnetic memory device as claimed in claim 12, wherein:
the memory portion includes a bottom electrode, a magnetic tunnel junction element, and a top electrode, which are sequentially stacked; and
the magnetic tunnel junction element includes a pinned layer, a tunnel barrier layer, and a free layer.

16. The magnetic memory device as claimed in claim 12, further comprising an insulation layer being at a lower level than the memory portion and covering a sidewall of the contact pad,
wherein the insulation layer includes an overlap region that vertically overlaps an edge of the memory portion and a non-overlap region that does not vertically overlap the memory portion, and
wherein the non-overlap region of the insulation layer has a top surface at lower level than a top surface of the overlap region.

17. A magnetic memory device, comprising:
a substrate including a first source/drain region and a second source/drain region;
a word line structure disposed between the first and source/drain regions and extending in a first direction;
a buried contact electrically connected to the first source/drain region and diposed on the first source/drain region, an upper width of the buried contact in a second direction perpendicular to the first direction being greater than a lower width of the buried contact in the second direction;
a contact pad electrically connected to the buried contact and disposed on the buried contact, the contact pad including the metal silicide layer; and
a memory portion electrically connected to the contact pad and disposed on the contact pad.

18. The magnetic memory device as claimed in claim 17, wherein the buried contact has a sloped sidewall.

19. The magnetic memory device as claimed in claim 17, wherein the contacts pad further includes a polysilicon pad contacting the metal silicide layer and the metal silicide layer contacts the memory portion.

20. The magnetic memory device as claimed in claim 17, wherein:
the contact pad further includes a metal pad contacting the metal silicide layer;
the metal silicide layer is between the metal pad and the buried contact; and
a width of the metal silicide layer in the second direction is substantially equal to the upper width of the buried contact in the second direction.
